(19) United States
(12) Patent Application Publication
(10) Pub. No.: US 2012/0085986 A1
(43) Pub. Date: Apr. 12, 2012

(54) GALLIUM NITRIDE-BASED COMPOUND SEMICONDUCTOR LIGHT-EMITTING DIODE

(75) Inventors: Junko Iwanaga, Osaka (JP); Toshiya Yokogawa, Nara (JP); Atsushi Yamada, Osaka (JP)

(73) Assignee: PANASONIC CORPORATION, Osaka (JP)

(21) Appl. No.: 13/321,923

(22) PCT Filed: Jun. 9, 2010
(86) PCT No.: PCT/JP2010/003847

§ 371 Date: Nov. 22, 2011

(30) Foreign Application Priority Data
Jun. 18, 2009 (JP) 2009-145652

(51) Int. Cl. H01L 33/04

(52) U.S. Cl. 257/9; 257/76; 257/E33.005

(57) ABSTRACT

The light-emitting diode element of this invention includes: an n-type GaN substrate (7), of which the principal surface (7a) is an m plane; and a multilayer structure on the principal surface (7a) of the substrate (7), which includes an n-type semiconductor layer (2), an active layer (3) on a first region (2a) of the upper surface of the n-type semiconductor layer (2), a p-type semiconductor layer (4), an anode electrode layer (5), and a cathode electrode layer (6) on a second region (2b) of the upper surface of the n-type semiconductor layer (2). These layers (2, 3, 4) have all been grown epitaxially through an m-plane growth. The n-type dopant concentration in the substrate (7) and n-type semiconductor layer (2) is 1×10¹⁸ cm⁻³ or less. When viewed perpendicularly to the principal surface (7a), a gap of 4 μm or less is left between the anode and cathode electrode layers (5, 6) and the anode electrode layer (5) is arranged at a distance of 45 μm or less from an edge of the cathode electrode layer (6) that faces the anode electrode layer (5).

### TECHNICAL FIELD

The present invention relates to a gallium nitride based compound semiconductor light-emitting diode and more particularly relates to a non-polar light emitting diode.

### BACKGROUND ART

A nitride semiconductor including nitrogen (N) as a Group V element is a prime candidate for a material to make a short-wave light-emitting device because its bandgap is sufficiently wide. Among other things, gallium nitride-based compound semiconductors (which will be referred to herein as “GaN-based semiconductors”) have been researched and developed particularly extensively. As a result, blue-ray-emitting light-emitting diodes (LEDs), green-ray-emitting LEDs and semiconductor laser diodes made of GaN-based semiconductors have already been used in actual products (see Patent Documents Nos. 1 and 2, for example).

A gallium nitride-based semiconductor has a wurtzite crystal structure. FIG. 1 schematically illustrates a unit cell of GaN. In an AlₐGa_{b}In_{c}N (where 0≦a, b, c≦1 and a+b+c=1) semiconductor crystal, some of the Ga atoms shown in FIG. 1 may be replaced with Al and/or In atoms.

FIG. 2 shows four fundamental vectors a₁, a₂, a₃ and c, which are generally used to represent planes of a wurtzite crystal structure with four indices (i.e., hexagonal indices). The fundamental vector c runs in the [0001] direction, which is called a “c axis”. A plane that intersects with the c axis at right angles is called either a “c plane” or a “(0001) plane”. It should be noted that the “c axis” and the “c plane” are sometimes referred to as “C axis” and “C plane”.

As shown in FIG. 3, the wurtzite crystal structure has other representative crystallographic plane orientations, not just the c plane. Portions (a), (b), (c) and (d) of FIG. 3 illustrate a (0001) plane, a (10-10) plane, a (11-20) plane, and a (10-12) plane, respectively. In this case, “-” attached on the left-hand side of a Miller-Bravais index in the parentheses means a “bar” (a negative direction index). The (0001), (10-10), (11-20) and (10-12) planes are c, m, a and r planes, respectively. The m and a planes are “non-polar planes” that are parallel to the c axis (represented by the fundamental vector c) but the r plane is a “semi-polar plane”.

Light-emitting devices that use gallium nitride based compound semiconductors have long been made by “c-plane growth” process. In this description, the “X-plane growth” means epitaxial growth that is produced perpendicularly to the X plane (where X=c, m, a or r, for example) of a hexagonal wurtzite structure. As for the X--plane growth, the X plane will be sometimes referred to herein as a “growing plane”. Furthermore, a layer of semiconductor crystals that have been formed as a result of the X-plane growth will be sometimes referred to herein as an “X-plane semiconductor layer”.

If a light-emitting device is fabricated as a semiconductor multilayer structure by c-plane growth process, then intense internal polarization will be produced perpendicularly to the c plane (i.e., in the c axis direction) because the c plane is a polar plane. Specifically, that polarization is produced because on the c-plane, Ga and N atoms are located at different positions with respect to the c axis. Once such polarization is produced in a light-emitting portion, the quantum confinement Stark effect of carriers will be generated. As a result, the probability of radiative recombination of carriers in the light-emitting portion decreases, thus decreasing the light-emitting efficiency as well.

To overcome such a problem, a lot of people have recently been making every effort to grow gallium nitride based compound semiconductors on a non-polar plane such as m or a plane or on a semi-polar plane such as an r plane. If a non-polar plane can be selected as a growing plane, then no polarization will be produced in the thickness direction of the light-emitting portion (i.e., in the crystal growing direction), and therefore, no quantum confinement Stark effect will be generated, either. Thus, a light-emitting device with potentially high efficiency can be fabricated. The same can be said even if a semi-polar plane is selected as a growing plane. That is to say, the influence of the quantum confinement Stark effect can be reduced significantly in that case, too.

A light-emitting diode currently retailed as a product is made by mounting, on a submount, a light-emitting diode element (LED chip) that has been fabricated by epitaxially growing GaN, InGaN, AlGaN and other GaN based semiconductor layers on a c-plane substrate. The planar size of such a light-emitting diode element (which means the planar dimensions of the principal surface of a substrate and which will be simply referred to herein as a “chip size”) changes according to the intended application of the light-emitting diode element. But the typical chip size is 300 μm×300 μm or 1 mm×1 mm.

Light-emitting diode elements can be roughly classified into the following two types according to the arrangement of their electrodes. One of the two is a so-called “double-sided electrode type” in which an anode electrode layer and a cathode electrode layer are arranged on the surface and back surface of a light-emitting diode element. The other is a so-called “surface electrode type” in which an anode electrode layer and a cathode electrode layer are both arranged on the surface of a light-emitting diode element. Hereinafter, structures of conventional light-emitting diode elements with those two types of electrode arrangements will be described.

FIG. 4A is a cross-sectional view illustrating a light-emitting diode element of the double-sided electrode type and FIG. 4B is a perspective view thereof. FIG. 5A is a cross-sectional view illustrating a light-emitting diode element of the surface electrode type and FIG. 5B is a top view thereof. FIG. 6A is a cross-sectional view illustrating another light-emitting diode element of the surface electrode type and FIG. 6B is a top view thereof.

In the example illustrated in FIGS. 4A and 4B, on an n-type substrate 1 of GaN, stacked in this order are an n-type conductive layer 2 of GaN, an active layer 3, and a p-type conductive layer 4 of GaN. In this example, the active layer 3 has a quantum well structure in which well layers (light-emitting layers) and barrier layers are stacked one upon the other. The well layers may be made of either InGaN or AlInGaN, while the barrier layers may be made of GaN. An anode electrode layer 5 has been formed on the p-type conductive layer 4, while a cathode electrode layer 6 has been formed on the back surface of the n-type substrate 1. In this example, the light that has been emitted by the active layer 3 is output from this light-emitting diode element through the back surface of the n-type substrate 1. That is why the cathode electrode layer 6 is made of a transparent electrode material. If the cathode electrode layer 6 needs to be made of an opaque conductor, then the cathode electrode layer 6 should be arranged in a particular area on the back surface of the n-type substrate 1 so as not to cut off the light. If a light-emitting diode element of the double-sided electrode type, of which the cathode electrode layer 6 is transparent, is mounted on a sub-mount, then the element should be mounted so that the anode electrode layer 5 faces the sub-mount.

On the other hand, in the example illustrated in FIGS. 5A and 5B, a cathode electrode layer 6 has been formed on a portion of the n-type conductive layer 2, which is exposed by removing respective parts of the p-type conductive layer 4, the active layer 3 and the n-type conductive layer 3. The anode electrode layer 5 is arranged on the p-type conductive layer 4. This type of light-emitting diode element is mounted on a sub-mount so that the anode electrode layer 5 and the cathode electrode layer 6 both face the sub-mount.

In the example illustrated in FIGS. 6A and 6B, in order to increase the ratio of the area of the active layer to the overall chip area, the area of the cathode electrode layer 6 is designed to be smaller than that of the cathode electrode layer 6 shown in FIG. 5B.

In the double-sided electrode type, the electrical resistance between the anode electrode layer 5 and the cathode electrode layer 6 is significantly affected by the resistance component of the GaN substrate 1. Thus, it is preferred that the resistance of the GaN substrate 1 be reduced as much as possible. A GaN semiconductor is usually doped with an n-type dopant more heavily than with a p-type dopant. That is why generally the lower resistance can be achieved more easily with an n-type dopant. For that reason, the conductivity type of the GaN substrate 1 is ordinarily defined to be n-type.

Likewise, as for the surface electrode type, since the electrical resistance between the anode electrode layer 5 and the cathode electrode layer 6 is affected by the resistance component of the GaN substrate 1, the conductivity type of the GaN substrate 1 is ordinarily defined to be n-type.

Such arrangements of electrodes have been adopted in c-plane light-emitting diode elements. However, the same arrangements are also applied as they are to m-plane light-emitting diode elements.

### CITATION LIST

### Patent Literature

Patent Document No. 1: Japanese Patent Application Laid-Open Publication No. 2001-308462

Patent Document No. 2: Japanese Patent Application Laid-Open Publication No. 2003-332697

### SUMMARY OF INVENTION

### Technical Problem

An m-plane GaN structure cannot be doped with a dopant, and cannot increase the carrier density, as easily as a c-plane GaN structure, which is a problem. And such a problem will arise in not just a GaN substrate but also an epitaxially grown GaN layer as well. Specifically, an m-plane GaN structure can have an n-type dopant concentration of about 5×10¹⁷ cm⁻³ to about 1×10¹⁸ cm⁻³. However, if its n-type dopant concentration should be raised from this level, then the quality of n-type GaN crystals would deteriorate noticeably and the surface state would degrade, too. As a result, the half width of PL would increase and the peak intensity of PL would decrease. And if crystals of such poor quality were used, non-radiative current and re-absorption of light would be produced much more often, thus causing a decrease in the efficiency of light-emitting diodes too much to sell them as products.

That is why to avoid such a decrease in crystal quality, the substrate and layers of n-type GaN cannot but have as low an n-type dopant concentration as 1×10¹⁸ cm⁻³ or less. However, if the dopant concentration was 1×10¹⁸ cm⁻³ or less, the voltage would drop due to high resistance and a sufficiently high voltage could not be applied to a portion of the active layer 3 that is located far away from the cathode electrode layer 5. As a result, the overall amount of current injected into the entire active layer 3 would decrease so much that the quantity of the light emitted would decrease steeply.

FIG. 7 is a graph showing how the current densities of a light-emitting diode of an m-plane double-sided electrode type and a light-emitting diode of an m-plane surface electrode type change with the dopant concentration of n-type GaN.

In this graph, the data plotted with the solid triangles A represents the current density of a light-emitting diode of the surface electrode type shown in FIGS. 5A and 5B, which was calculated based on a given n-type dopant concentration (or carrier concentration). In this example, the gap between the anode electrode layer 5 and the cathode electrode layer 6 was fixed at 10 μm and the length of the anode electrode layer 5 was changed within the range of 20 μm to 400 μm. On the other hand, the data plotted with the solid squares ▪ represents the current density of a light-emitting diode of the double-sided electrode type shown in FIGS. 4A and 4B, which was also calculated based on a given n-type dopant concentration. In any of these cases, the GaN substrate had a thickness of about 100 μm.

As can be seen from this graph, the lower the dopant concentration (or carrier concentration), the lower the current density in both of the double-sided electrode type and the surface electrode type. When the dopant concentration was the same, the double-sided electrode type achieved a higher current density than the surface electrode type. This is because in the double-sided electrode type, an electric field is applied uniformly to the active layer, and therefore, a larger amount of current flows more easily than in the surface electrode type. In the surface electrode type, the larger the area of the anode electrode layer, the larger the area of the active layer. That is why if the same voltage is applied, a sufficiently high voltage cannot be applied to a portion of the active layer that is located far away from the cathode electrode. As a result, the density of the current flowing through the active layer decreases.

According to the results of calculations described above, in a light-emitting diode that has been fabricated by m-plane growth process, n-type GaN has so low a dopant concentration that the current density decreases and the quantity of the light emitted will decrease or become uneven. As a result, the advantages that should be achieved by using a non-polar plane cannot be taken fully.

It is therefore an object of the present invention to provide a light-emitting diode of the surface electrode type that uses non-polar GaN based semiconductors with a low dopant concentration but that can inject a sufficiently large amount of current into the active layer uniformly and can exhibit a good enough emission characteristic.

### Solution to Problem

A gallium nitride based compound semiconductor light-emitting diode element according to the present invention includes: a semiconductor substrate of a first conductivity type, which is made of a gallium nitride based compound, which has a principal surface and a back surface, and of which the principal surface is a non-polar plane; a semiconductor layer of the first conductivity type, which is also made of a gallium nitride based compound and which has been formed on the principal surface of the semiconductor substrate of the first conductivity type; a semiconductor multilayer structure, which is arranged on a first region of the semiconductor layer of the first conductivity type and which includes a semiconductor layer of a second conductivity type that is made of a gallium nitride based compound and an active layer that is arranged between the semiconductor layer of the first conductivity type and the semiconductor layer of the second conductivity type; a first electrode layer, which is arranged on a second region of the semiconductor layer of the first conductivity type; and a second electrode layer, which is arranged on the semiconductor layer of the second conductivity type. A dopant of the first conductivity type added to the semiconductor substrate of the first conductivity type and the semiconductor layer of the first conductivity type has a concentration of 1×10¹⁸ cm⁻³ or less. When viewed perpendicularly to the principal surface, a gap of 4 μm or less is left between the first and second electrode layers and the second electrode layer is arranged at a distance of 45 μm or less from an edge of the first electrode layer that faces the second electrode layer.

In one preferred embodiment, the first electrode layer has multiple extended portions that run in a first direction, and the second electrode layer has a portion that is located in a region interposed between two of the extended portions of the first electrode layer.

In this particular preferred embodiment, the first electrode layer has at least one interconnecting portion that electrically connects the multiple extended portions together, and the interconnecting portion runs in a second direction, which is different from the first direction.

In another preferred embodiment, the second electrode layer has multiple extended portions that run in a first direction, and the first electrode layer has a portion that is located in a region interposed between two of the extended portions of the second electrode layer.

In still another preferred embodiment, each of the first and second electrode layers has multiple extended portions that run in a first direction, and the extended portions of the first electrode layer and the extended portions of the second electrode layer are arranged alternately in a second direction that is different from the first direction.

In this particular preferred embodiment, the first electrode layer has at least one first interconnecting portion that electrically connects its own extended portions together. The second electrode layer has at least one second interconnecting portion that electrically connects its own extended portions together. And the first and second interconnecting portions run in a second direction that is different from the first direction.

In still another preferred embodiment, the second electrode layer has a plurality of openings, and the first electrode layer includes electrodes, which are arranged inside of the openings of the second electrode layer.

In a specific preferred embodiment, when viewed perpendicularly to the principal surface, those electrodes that are arranged inside of the openings of the second electrode layer have a curved outer edge.

In yet another preferred embodiment, the first electrode layer has a plurality of openings, and the second electrode layer includes electrodes, which are arranged inside of the openings of the first electrode layer.

In this particular preferred embodiment, the semiconductor multilayer structure has been divided into as many parts as the openings of the first electrode layer.

In a specific preferred embodiment, the first electrode layer has a conductive portion with a grating shape that defines the openings.

In a more specific preferred embodiment, the number of the openings is eight or more.

In yet another preferred embodiment, the principal surface of the semiconductor substrate of the first conductivity type is smaller than a square with a length of 50 ∞m each side.

In this particular preferred embodiment, current that flows between the first and second electrode layers when the diode element operates has a density of 150 A/cm² or more.

In yet another preferred embodiment, the active layer has a quantum well structure in which a well layer and a barrier layer are stacked one upon the other and the well layer has a thickness of 6 nm to 20 nm.

### Advantageous Effects of Invention

A gallium nitride based compound semiconductor light-emitting diode element according to the present invention includes a semiconductor substrate of a gallium nitride based compound with a non-polar plane and has an n-type dopant concentration of 1×10¹⁸ cm⁻³ or less, and therefore, has a good degree of crystallinity. In addition, the light-emitting diode element is a surface electrode type but adopts a special electrode arrangement so that a sufficiently high voltage can be applied to the entire active layer. As a result, a high optical output can be obtained and the in-plane distribution of the light emitted can be turned into a uniform one easily.

### BRIEF DESCRIPTION OF DRAWINGS

FIG. 1 is a perspective view schematically illustrating a unit cell of GaN.

FIG. 2 is a perspective view showing four fundamental vectors a₁, a₂, a₃ and c that represent a wurtzite crystal structure.

Portions (a) through (d) of FIG. 3 are schematic representations showing representative crystallographic plane orientations of a hexagonal wurtzite crystal structure.

FIG. 4A is a cross-sectional view illustrating a light-emitting diode element of a double-sided electrode type.

FIG. 4B is a perspective view of the light-emitting diode element shown in FIG. 4A.

FIG. 5A is a cross-sectional view illustrating a light-emitting diode element of a surface electrode type.

FIG. 5B is a top view of the light-emitting diode element shown in FIG. 5A.

FIG. 6A is a cross-sectional view illustrating another light-emitting diode element of the surface electrode type.

FIG. 6B is a top view of the light-emitting diode element shown in FIG. 6A.

FIG. 7 is a graph showing how the current densities of a light-emitting diode of a double-sided electrode type and a light-emitting diode of a surface electrode type change with the dopant concentration of n-type GaN.

FIG. 8 is a cross-sectional view illustrating a light-emitting diode element according to a first preferred embodiment of the present invention as viewed on the plane B-B′ shown in FIG. 9.

FIG. 9 is a top view of the light-emitting diode shown in FIG. 8.

FIG. 10A is a cross-sectional view illustrating a light-emitting diode element in which the anode electrode layer 5 is interposed between two portions of the cathode electrode layer 6.

FIG. 10B is a plan view schematically illustrating the arrangement of the electrode layers 5 and 6 shown in FIG. 10A.

FIG. 11A is a cross-sectional view illustrating a light-emitting diode element in which the cathode electrode layer 6 is arranged on only one side of the anode electrode layer 5.

FIG. 11B is a plan view illustrating the arrangement of major parts of the electrode layers 5 and 6 shown in FIG. 11A.

FIG. 12A is a graph showing, based on the data obtained through simulations, how an optical output ratio changed with the distance L.

FIG. 12B is a graph showing, based on the data obtained through simulations, how an optical output ratio changed with the distance L.

FIG. 13 is a graph showing the emission intensity distribution on the plane A-A′ shown in FIG. 8.

FIG. 14A is a graph showing the distribution (on the cross section A-A′) of the rate of recombination Rap of a light-emitting diode of the surface electrode type shown in FIG. 8.

FIG. 14B is a graph plotted based on the data shown in

FIG. 14A and shows how the minimum value of the rate of recombination Rsp of spontaneous emission changes with the anode-cathode electrode gap Lao.

FIG. 15A is a cross-sectional view illustrating a second preferred embodiment of a light-emitting diode according to the present invention as viewed on the plane C-C′ shown in FIG. 15B.

FIG. 15B is a top view illustrating the light-emitting diode of the second preferred embodiment of the present invention.

FIG. 16A is a cross-sectional view illustrating a third preferred embodiment of a light-emitting diode according to the present invention as viewed on the plane D-D′ shown in FIG. 16B.

FIG. 16B is a top view illustrating the light-emitting diode of the third preferred embodiment of the present invention.

FIG. 17 is a cross-sectional view illustrating a fourth preferred embodiment of a light-emitting diode according to the present invention as viewed on the plane E-E′ shown in FIG. 18.

FIG. 18 is a top view illustrating the light-emitting diode of the fourth preferred embodiment of the present invention.

FIG. 19 is a cross-sectional view illustrating a fifth preferred embodiment of a light-emitting diode according to the present invention as viewed on the plane H-H′ shown in FIG. 20.

FIG. 20 is a top view illustrating the light-emitting diode of the fifth preferred embodiment of the present invention.

FIG. 21A is a top view of a sample light-emitting diode representing a comparative example, of which the distance L had a maximum value of 175 μm.

FIG. 21B is a top view of another sample light-emitting diode representing a specific example of the present invention, of which the distance L had a maximum value of 45 μm.

FIG. 21C is a top view of another sample light-emitting diode representing another specific example of the present invention, of which the distance L had a maximum value of 18 μm.

FIG. 22A is a graph showing, based on the results of experiments, how the optical output ratio changed with the distance L.

FIG. 22B is a graph showing, based on the results of experiments, how the maximum value of the external quantum efficiency changed with the distance L.

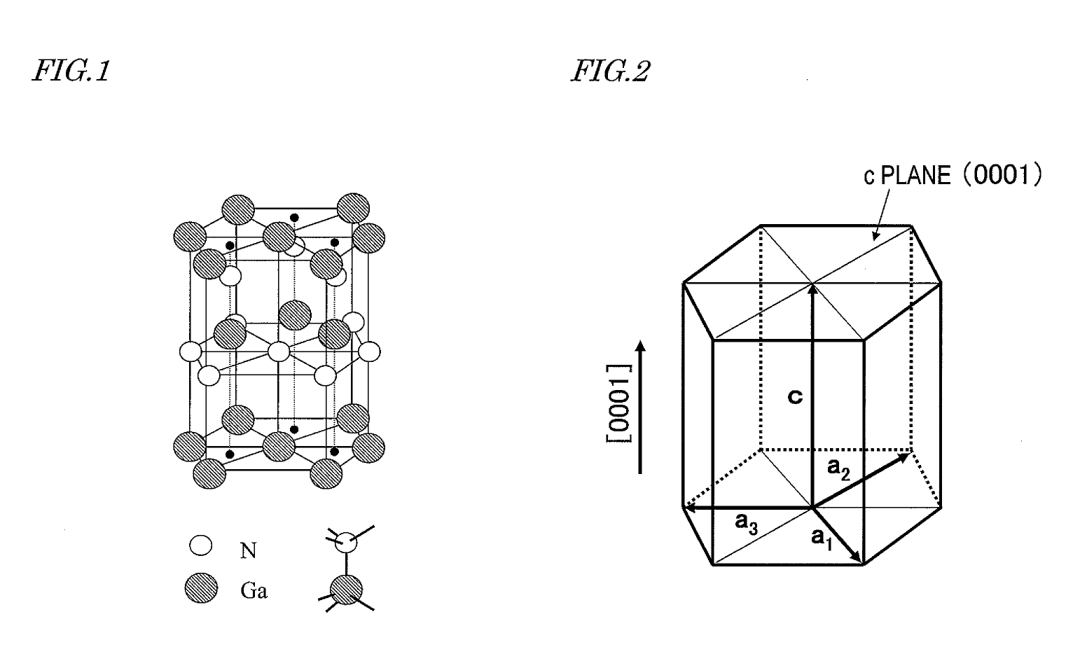

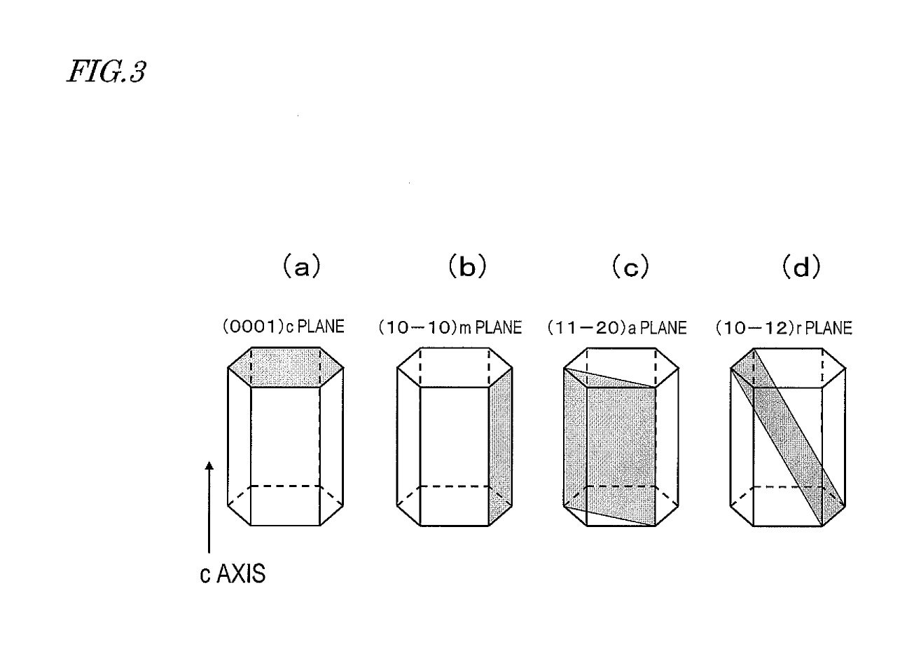

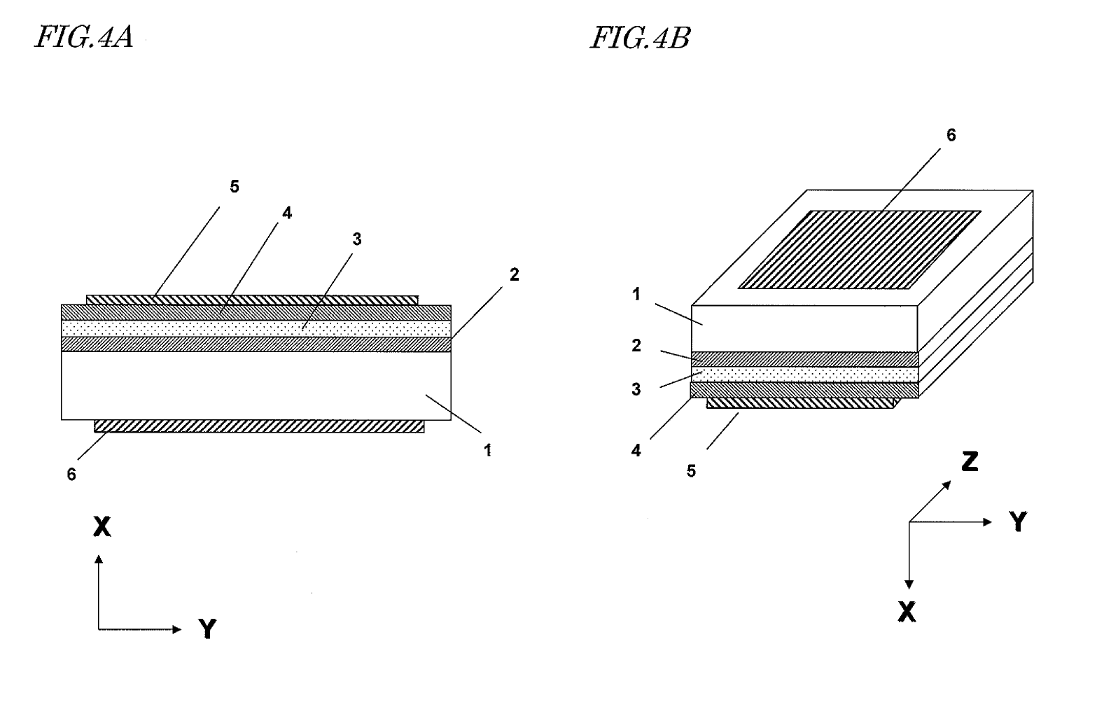

### DESCRIPTION OF EMBODIMENTS

### Embodiment 1

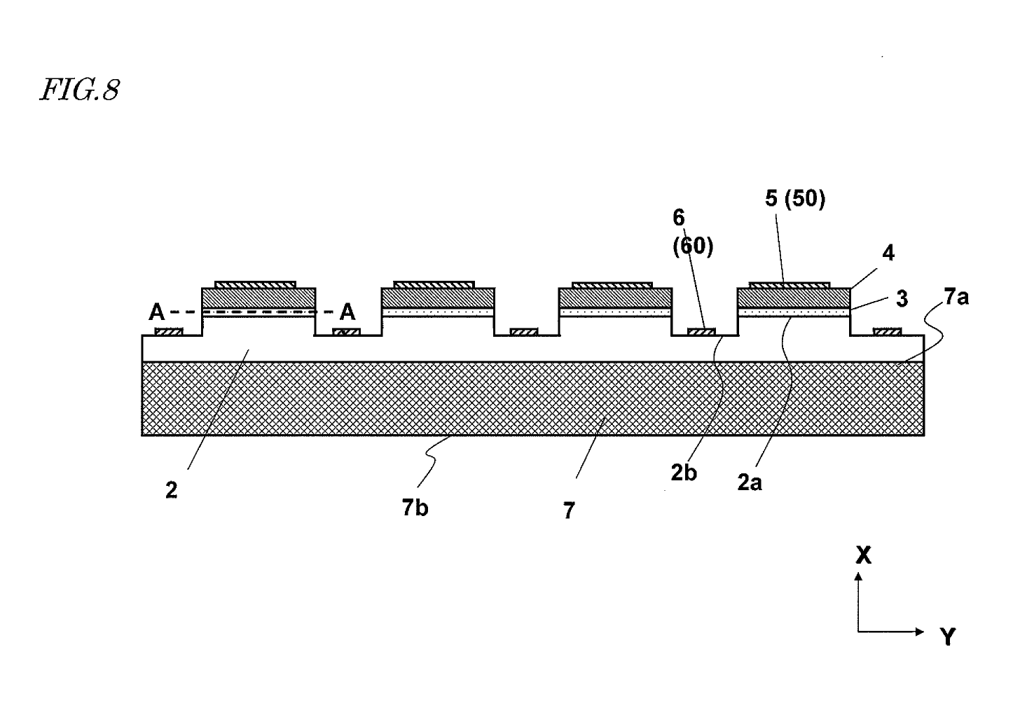

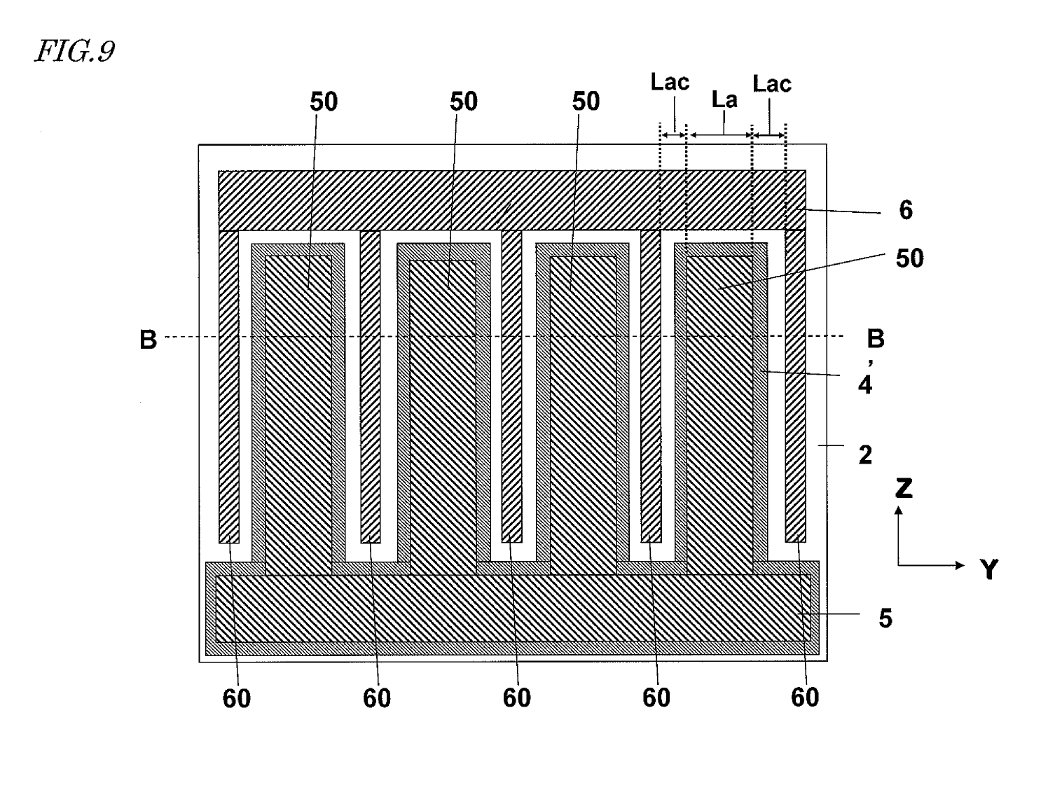

First of all, a first specific preferred embodiment of a light-emitting diode according to the present invention will be described with reference to FIGS. 8 and 9. FIG. 8 is a cross-sectional view illustrating a light-emitting diode according to this first preferred embodiment, while FIG. 9 is a top view of the light-emitting diode shown in FIG. 8. And FIG. 8 is a cross-sectional view as viewed on the plane B-B′ shown in FIG. 9. In the accompanying drawings, a YZ plane of an XYZ coordinate system is supposed to be parallel to the principal surface of the substrate and the X-axis is supposed to be perpendicular to the principal surface of the substrate.

As shown in FIG. 8, the light-emitting diode of this preferred embodiment includes an n-type GaN substrate 7, of which the principal surface 7a is an m plane, and a multilayer structure, which is arranged on the principal surface 7a of the n-type GaN substrate 7. It should be noted that the “m-plane” is a generic term that refers to any of a family of planes including (10-10), (-1010), (1-100), (-1100), (01-10) and (0-110) planes. The light-emitting diode of this preferred embodiment is a surface electrode type and no electrode is provided at all for the back surface 7b of the n-type GaN substrate 7.

The multilayer structure on the n-type GaN substrate includes an n-type semiconductor layer 2 that covers the principal surface of the n-type GaN substrate 7, an active layer 3 that is located on a first region 2a of the upper surface of the n-type semiconductor layer 2, a p-type semiconductor layer 4 stacked on the active layer 3, an anode electrode layer 5 arranged on the p-type semiconductor layer 4, and a cathode electrode layer 6 arranged on a second region 2b of the upper surface of the n-type semiconductor layer 2. All of the n-type semiconductor layer 2, the active layer 3 and the p-type semiconductor layer 4 have been grown epitaxially through an m-plane growth process.

As described above, it is difficult to introduce an n-type dopant into a GaN based semiconductor layer formed by m-plane growth process. And if its n-type dopant concentration was set to be higher than 1×10¹⁸ cm⁻³, then the quality of crystals grown would deteriorate significantly. In view of this consideration, according to this preferred embodiment, the n-type dopant concentration in the n-type GaN substrate 7 and the n-type semiconductor layer 2 is set to be equal to or lower than 1×10¹⁸ cm⁻³ so that their crystallinity will be good enough. The n-type GaN substrate 7 may have an n-type dopant concentration of 1×10¹⁷ cm⁻³ to 1×10¹⁸ cm⁻³, for example, and typically has a dopant concentration of about 5×10¹⁷ cm⁻³.

After an epitaxial growth process and an electrode forming process have been finished, the n-type GaN substrate 7 may be polished or etched from its back surface 7b to have its thickness reduced. The final thickness of the n-type GaN substrate 7 falls within the range of 5 μm to 250 μm, for example.

If flip-chip bonding has been carried out, the light emitted from the active layer 3 is transmitted through the n-type GaN substrate 7 and output through its back surface 7b. In that case, to output the light efficiently, it is preferred that the n-type GaN substrate 7 have its thickness reduced as much as possible to minimize the absorption loss caused by the n-type GaN substrate 7. Nevertheless, if the n-type GaN substrate 7 were too thin, then its mechanical strength would be too low to handle the light-emitting diode element easily in a mounting process. Thus, taking all of these factors into consideration, the standard thickness of the n-type GaN substrate 7 is finally set to be about 100 μm, for example.

The n-type semiconductor layer 2 functions as a buffer layer when an epitaxial growth process starts to be performed on the n-type GaN substrate 7. At its thickest part, the n-type semiconductor layer 2 may have a thickness of at most about 5 μm, for example. Optionally, an AlGaN layer may be inserted as an overflow stopper layer that reduces the overflow of carriers between the active layer 3 and the p-type semiconductor layer

If GaN based semiconductor layers that have been formed by m-plane growth process are used, the active layer can be thicker than a situation where GaN based semiconductor layers that have been formed by c-plane growth process are used. As a result, the density of current flowing through the active layer when the diode is operating (i.e., the current density) can be increased without decreasing the emission efficiency. Thus, in a preferred embodiment of the present invention, the diode can operate with the current density raised to 150 A/cm² or more. In an application that requires an even higher optical output, the diode preferably operates with the current density raised to 300 A/cm² or more. Nevertheless, the upper limit of the current density depends on the heat dissipation ability of the element. And if the current density exceeds 800 A/cm², some heat will be generated to cause a decrease in efficiency eventually. For that reason, the current density is preferably set to be equal to or lower than 800 A/cm².

Hereinafter, an example of a preferred manufacturing process for making a light-emitting diode according to this preferred embodiment will be described with reference to FIG. 8.

First of all, an n-type GaN substrate 7, of which the principal surface 7a is an m plane, is provided. Such an n-type GaN substrate may be obtained by HVPE (hydride vapor phase epitaxy) process. For example, a thick GaN film is grown to a thickness of several millimeters on a c-plane sapphire substrate, and then diced perpendicularly to the c plane (i.e., parallel to the m plane), thereby obtaining m-plane GaN substrates. However, the GaN substrate does not have to be prepared by this particular method. Alternatively, an ingot of bulk GaN may be made by a liquid phase growth process such as a sodium flux process or a melt growth process such as an ammono-thermal process and then diced parallel to the m-plane.

In this preferred embodiment, crystal layers are formed one after another on the substrate 7 by MOCVD (metalorganic chemical vapor deposition) process. First of all, an AlᵤGaᵥIn_{w}N layer is formed as the n-type semiconductor layer 2 on the n-type GaN substrate 7. As the AlᵤGaᵥIn_{w}N layer, a GaN layer may be deposited to a thickness of 3 μm, for example. To form a GaN layer as the AlᵤGaᵥIn_{w}N layer, TMG(Ga(CH₃)₃), TMA(Al(CH₃)₃) and NH₃ gases may be supplied onto the n-type GaN substrate 7 at 1100° C., for example, thereby depositing a GaN layer. Next, an active layer 3 is formed on the n-type semiconductor layer 2. In this example, the active layer 3 has a GaInN/GaN multi-quantum well (MQW) structure in which Ga_{0.9}In_{0.1}N well layers and GaN barrier layers, each having a thickness of 9 nm, have been stacked alternately to have an overall thickness of 81 nm. When the Ga_{0.9}In_{0.1}N well layers are formed, the growth temperature is preferably lowered to 800° C. to introduce In. Optionally, the well layers may also be made of AlInGaN instead of GaInN. Thereafter, a p-type semiconductor layer 4 of p-A1_{0.14}Ga_{0.86}N is deposited to a thickness of 70 nm, for example, on the active layer 3 by supplying TMG, NH₃, TMA, TMI gases and Cp₂Mg (cyclopentadienyl magnesium) gas as a p-type dopant. The p-type semiconductor layer 4 preferably has a p-GaN contact layer (not shown) on its surface.

After the epitaxial growth by the MOCVD process has been finished, respective portions of the p-type semiconductor layer 4 and the active layer 3 are removed by performing a chlorine-based dry etching process, thereby making a recess and exposing a region of the n-type semiconductor layer 2 where an n-electrode will be formed. Then, Ti/Pt layers are deposited there to form a cathode electrode layer 6. Meanwhile, in the p-type semiconductor region 4, an anode electrode layer 5 of Pd/Pt layers, for example, is formed.

These semiconductor layers and electrode layers may be formed by known manufacturing technologies. Thus, the foregoing description of the manufacturing process is just a description of a preferred embodiment of the present invention.

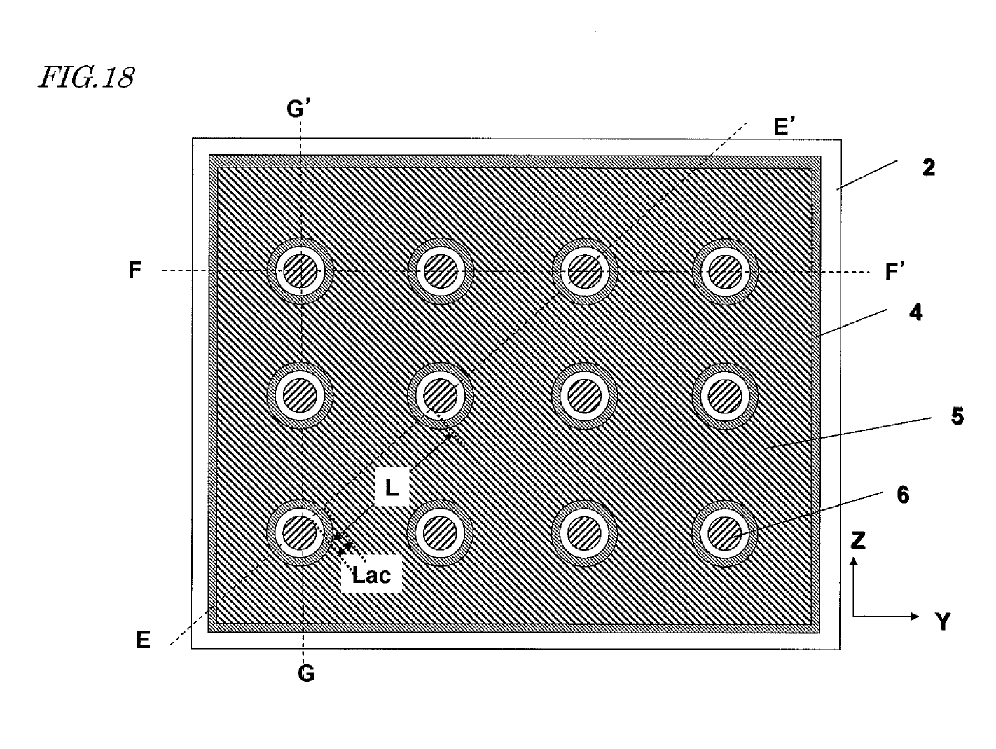

According to this preferred embodiment, the anode electrode layer 5 and the cathode electrode layer 6 have a comb shape or finger shape planar layout as shown in FIG. 9. In the cross-sectional view shown in FIG. 8, each of the anode electrode layer 5 and the cathode electrode layer 6 appears to have been divided into multiple electrode portions. Actually, however, each of the anode electrode layer 5 and the cathode electrode layer 6 is made of the same conductive layer as can be seen easily from FIG. 9. However, at least one of the anode and cathode electrode layers 5 and 6 may be made up of multiple physically separated electrodes. In fact, in a preferred embodiment of the present invention to be described later with reference to FIG. 17, the cathode electrode layer 6 consists of multiple circular electrodes, which are electrically connected together with a conductive layer or a conductive wire (neither is shown) and have substantially the same potential (cathode potential). Thus, those circular electrodes form a cathode electrode layer. In this description, a conductive member consisting of at least one electrode that is/are electrically connected together to have substantially the same potential will be referred to herein as an “electrode layer”. Such an electrode layer may be obtained by patterning a conductive film (which may be a single layer or a stack of multiple of layers).

As shown in FIG. 8, the cathode electrode layer 6 of this preferred embodiment is arranged on the second region 2b of the n-type semiconductor layer 2, from which the p-type semiconductor layer 4 and the active layer 3 have been removed selectively. That is why the larger the area of the cathode electrode layer 6, the smaller the area of the active layer 3. For that reason, according to this preferred embodiment, the area of the cathode electrode layer 6 is set to be smaller than that of the anode electrode layer 5 in order to increase the area of the active layer 3.

As shown in FIG. 9, the anode electrode layer 5 of this preferred embodiment has multiple extended portions 50 that run in the Z-axis direction. Likewise, the cathode electrode layer 6 also has multiple extended portions 60 that run in the Z-axis direction. In the example illustrated in FIG. 9, each extended portion 50 of the anode electrode layer is arranged between two associated ones of the extended portions 60 of the cathode electrode layer 6. In this description, when the light-emitting diode is viewed perpendicularly to the principal surface 7a of the n-type GaN substrate 7, the gap between the anode electrode layer 5 and the cathode electrode layer 6 will be referred to herein as an “anode-cathode electrode gap Lac” and the size of each extended portion 50 of the anode electrode layer 5 as measured in the current path direction will be referred to herein as an “anode electrode length La”. In the drawings, the anode-cathode electrode gap Lac and the anode electrode length La are simply identified by Lac and La, respectively, for the sake of simplicity.

For the reasons to be described later, according to this preferred embodiment, the arrangement of the electrodes is designed so as to satisfy Lac≦4 μm and 2·Lac+La≦90 μm. In this case, as can be seen easily from FIG. 9, 2·Lac+La corresponds to the interval between two extended portions 60 of the cathode electrode layer 6 that interpose one extended portion 50 of the anode electrode layer 50. If this interval is set to be equal to or smaller than 90 μm, the shortest distance from an arbitrary position on the anode electrode layer 5 to the cathode electrode layer 6 becomes 45 μm or less.

The respective extended portions 50 of the anode electrode layer 5 are electrically connected together with an interconnecting portion that runs in the Y direction. That interconnecting portion is made of the same conductor layer as the anode electrode layer 5 and forms part of the anode electrode layer 5. Likewise, the respective extended portions 60 of the cathode electrode layer 6 are also electrically connected together with another interconnecting portion that runs in the Y direction, too. That another interconnecting portion is made of the same conductor layer as the cathode electrode layer 6 and forms part of the cathode electrode layer 6. However, those interconnecting portions may also be made of another conductor layer or conductive wire. For example, those interconnecting portions may be arranged so as to cross those extended portions 50 and 60 overhead.

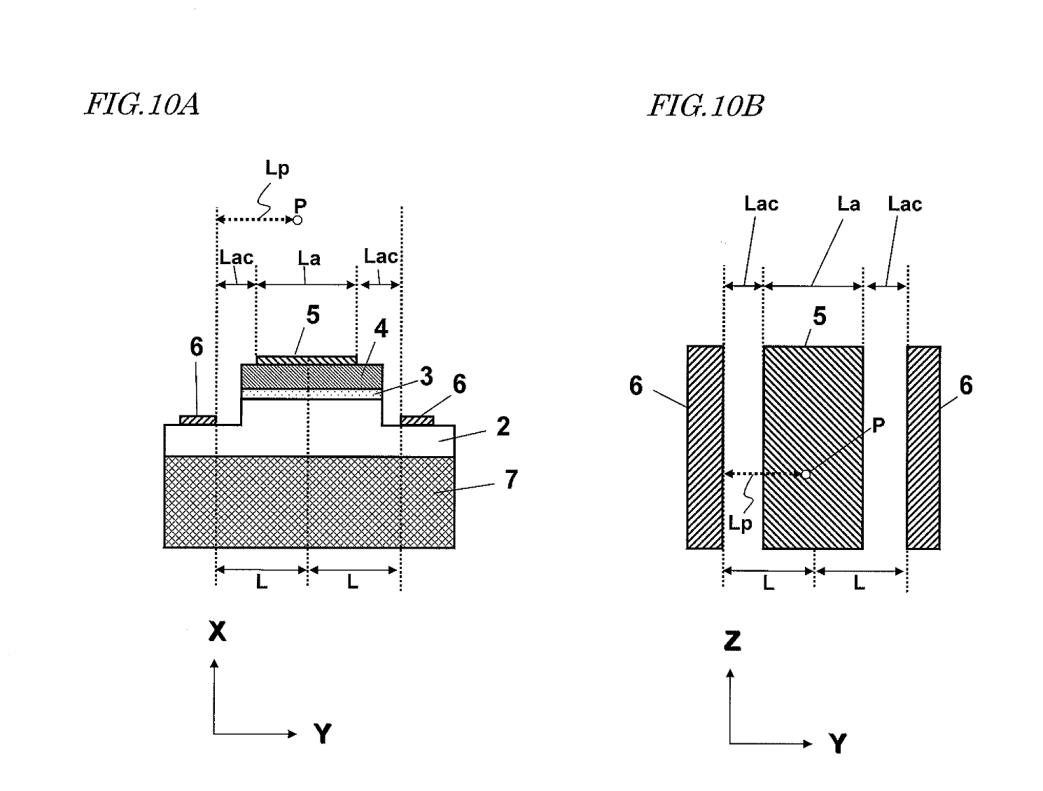

Next, turn to FIGS. 10A and 10B. FIG. 10A is a cross-sectional view illustrating a light-emitting diode element in which the anode electrode layer 5 is interposed between two portions of the cathode electrode layer 6, while FIG. 10B is a plan view schematically illustrating the arrangement of such electrode layers 5 and 6. In the exemplary arrangement illustrated in FIGS. 10A and 10B, two portions of the cathode electrode layer 6 are arranged on right- and left-hand sides of the anode electrode layer 5 with a gap Lac left between them. That is to say, the gap Lac is the distance from a portion of the outer edge of the cathode electrode layer 6 that faces the anode electrode layer 5 (which will be referred to herein as a “counter edge portion” of the cathode electrode layer 6) to a portion of the outer edge of the anode electrode layer 5 that faces the cathode electrode layer 5 (which will be referred to herein as a “counter edge portion” of the anode electrode layer 5). In this preferred embodiment, this gap Lac is set to be 4 μm or less. The lower limit of this gap Lac is defined by manufacturing process technologies and may be 0.5 μm, for example.

In the example illustrated in FIGS. 10A and 10B, the anode electrode layer 5 does not exist at a distance of more than 45 μm from the counter edge portion of the cathode electrode layer 6. That is to say, any part of the anode electrode layer 5 is located within 45 μm from the counter edge portion of the cathode electrode layer 6.

Hereinafter, this point will be described in further detail with reference to FIG. 10B. Suppose an arbitrary point on the anode electrode layer 5 is identified by P and the distance from that point P to the closest counter edge of the cathode electrode layer 6 is identified by Lp. The distance Lp does vary according to the position of the point P but never exceeds (2·Lac+La)/2. That is to say, the maximum value L of the distance Lp is (2·Lac+La)/2. As 2·Lac+La≦90 μm according to this preferred embodiment, (2·Lac+La)/2 is equal to or smaller than 45 μm. In other words, the anode electrode layer 5 is located within the distance L (=45 μm) from the counter edge of the cathode electrode layer 6.

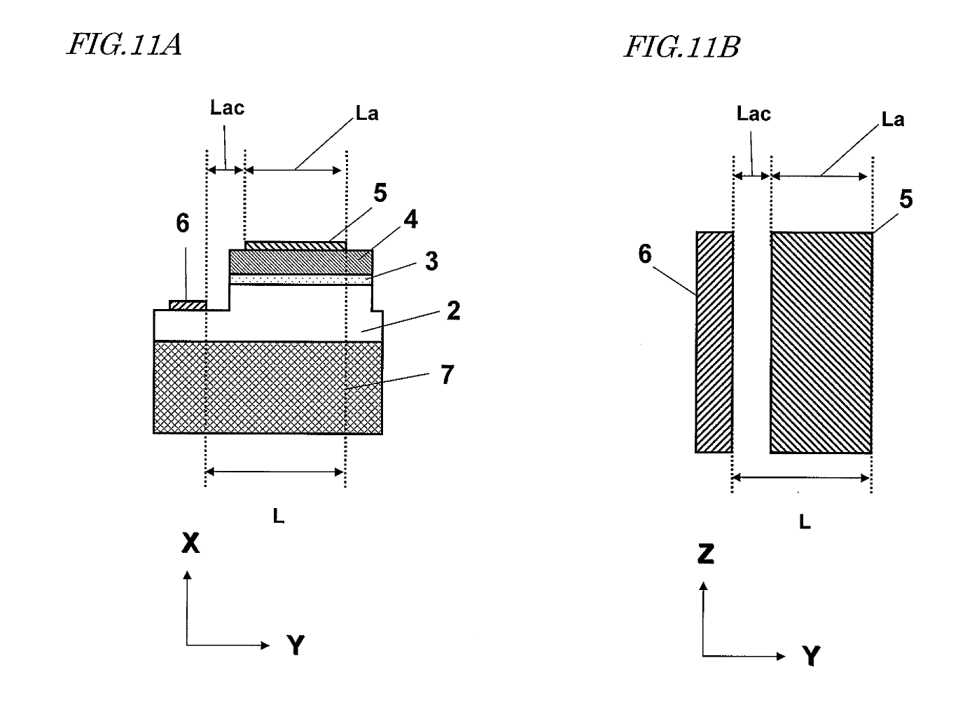

Next, take a look at FIGS. 11A and 11B. FIG. 11A is a cross-sectional view illustrating a light-emitting diode element in which the cathode electrode layer 6 is arranged on only one side of the anode electrode layer 5, while FIG. 11B is a plan view illustrating the arrangement of major parts of such electrode layers 5 and 6. In the exemplary arrangement shown in FIGS. 11A and 11B, the cathode electrode layer 6 is arranged on one side (e.g., on the left-hand side) of the anode electrode layer 5 with a gap Lac of 4 μm or less left between them. In the example illustrated in FIGS. 11A and 11B, the anode electrode layer 5 does not exist at a distance of more than 45 μm (that is the distance L) from the counter edge portion of the cathode electrode layer 6. That is to say, any part of the anode electrode layer 5 is located within the distance L (=45 μm) from the counter edge portion of the cathode electrode layer 6 Also, in the example illustrated in FIGS. 11A and 11B, Lac+La≦45 μm is satisfied.

After all, according to the present invention, no matter whether the cathode electrode layer 6 is arranged on both sides of the anode electrode layer 5 or only one side thereof, the anode electrode layer 5 is always arranged at a distance of 45 μm or less from the counter edge portion of the cathode electrode layer 6. It should be noted that even if any part of the anode electrode layer 5 is located outside of that range but if that part accounts for 10% or less of the overall area of the cathode electrode layer 6, the effects of the present invention can still be achieved.

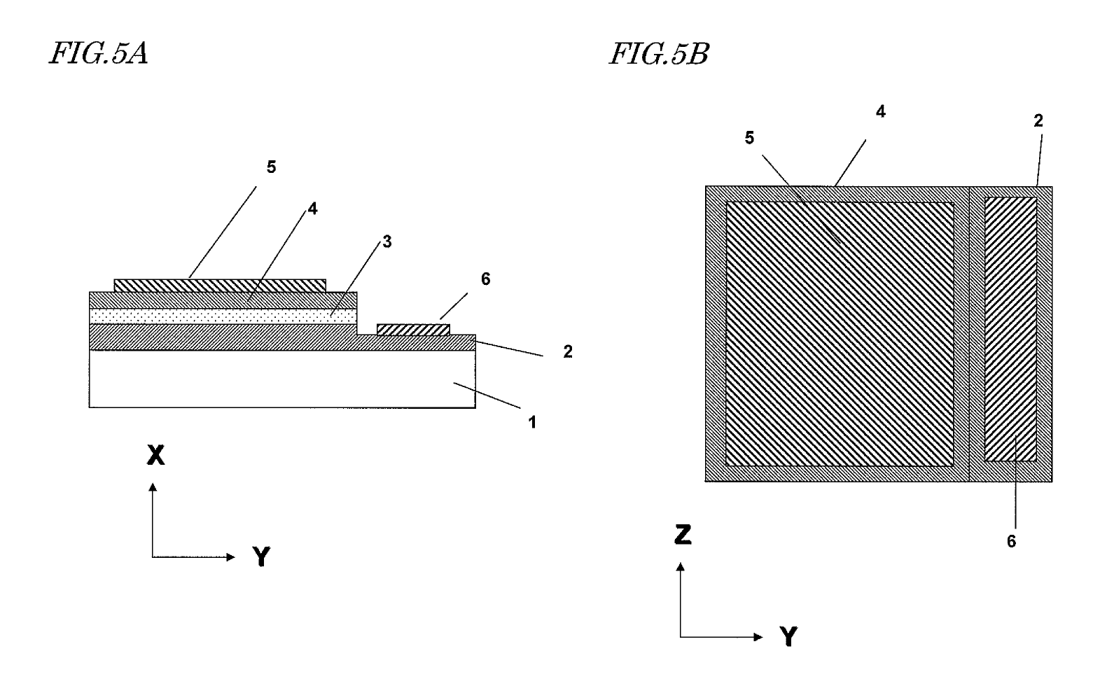

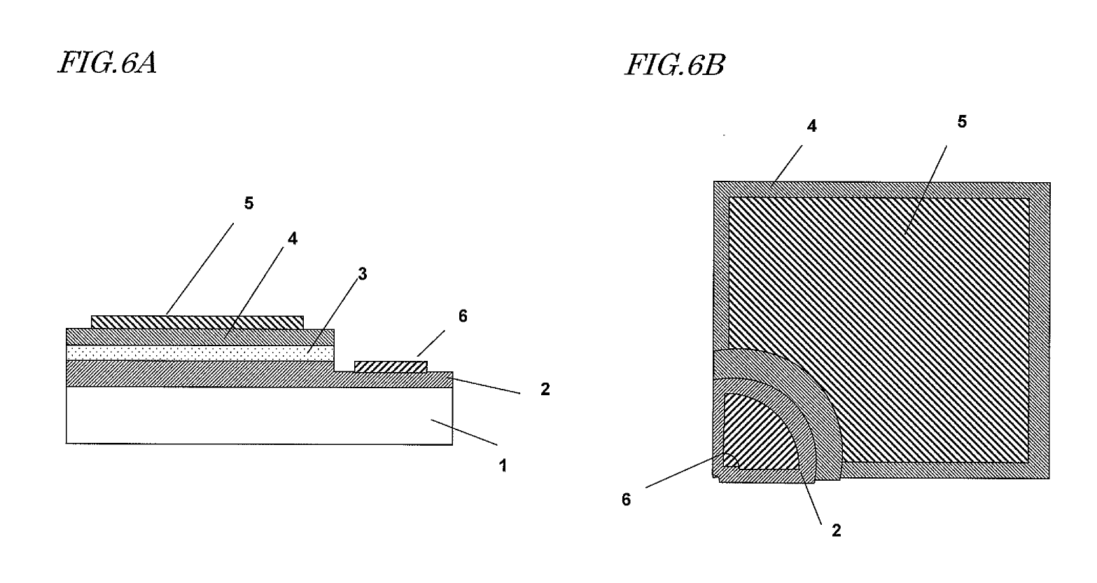

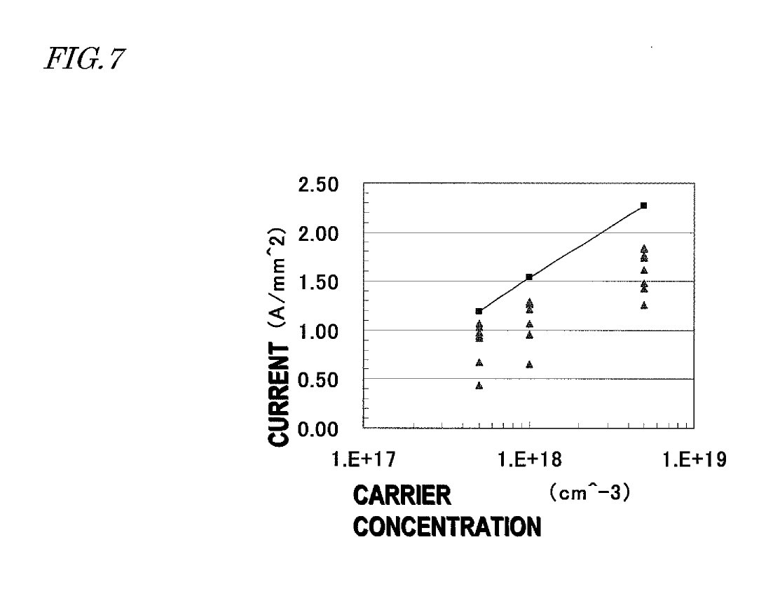

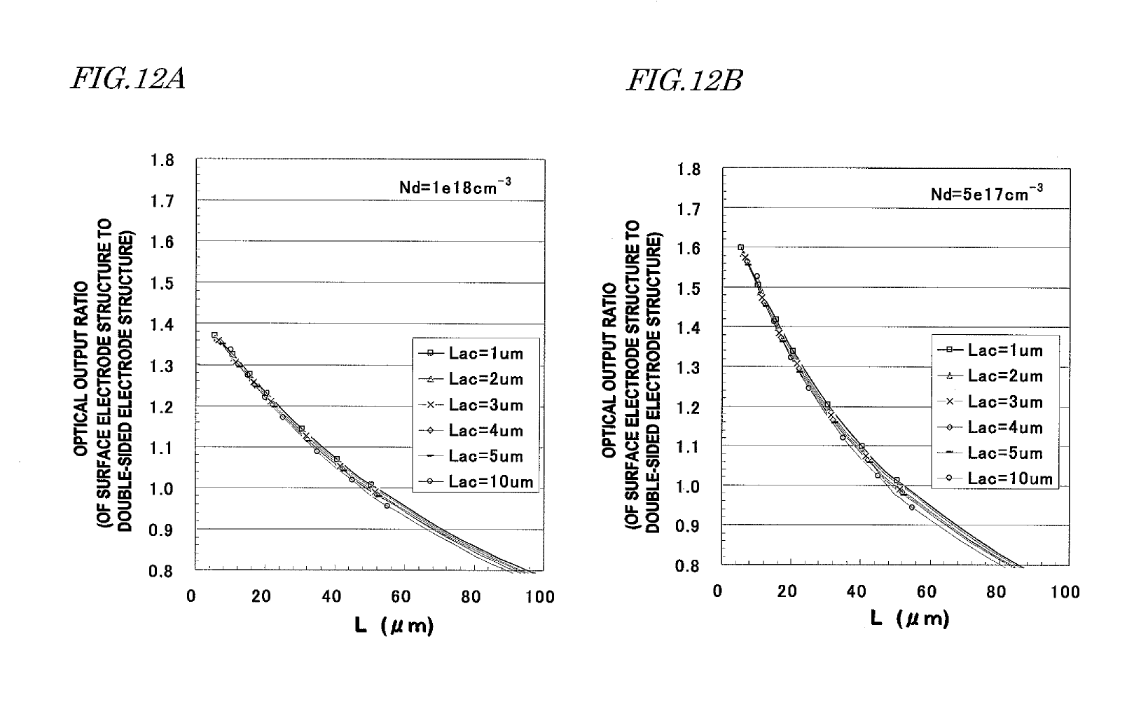

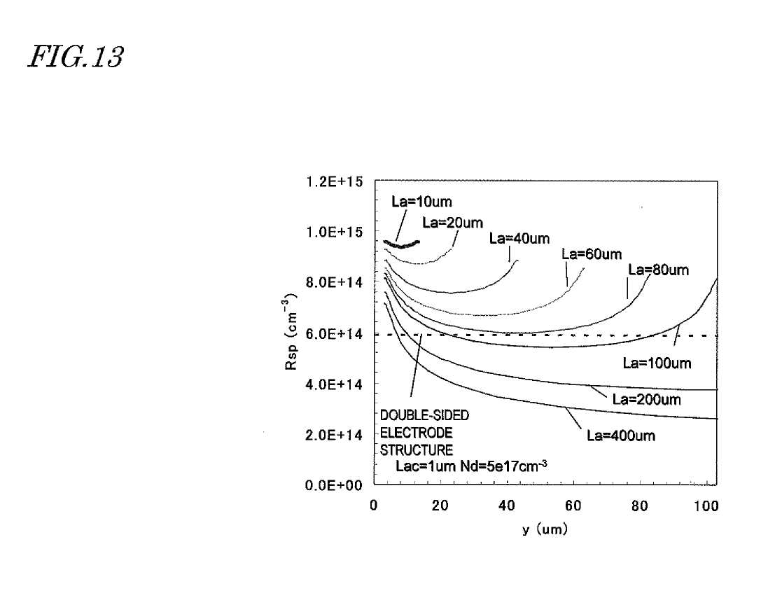

Next, it will be described with reference to FIGS. 12A and 12B why the anode electrode layer 5 should be arranged at that distance of 45 μm or less from the counter edge portion of the cathode electrode layer 6. FIGS. 12A and 12B are graphs showing how an optical output ratio changed with the distance L. The data plotted in these graphs was obtained by making simulations. In this case, the “optical output ratio” was normalized by dividing the optical output of the light-emitting diode with the structure shown in FIGS. 5A and 5B by that of a light-emitting diode of the double-sided electrode type, which had the same structure as the former light-emitting diode except the electrodes. The distance L is the one shown in FIG. 10B and L=(2·Lac+La)/2. In these graphs, results of calculations obtained by changing the anode-cathode electrode gap Lac within the range of 1 μm through 10 μm are plotted. In these graphs, “Nd=1e18 cm⁻³” indicates that the n-type dopant concentration was 1×10¹⁸ cm⁻³ and “Nd=5e17 cm⁻³” indicates that the n-type dopant concentration was 5×10¹⁷ cm⁻³.

As can be seen from the graphs shown in FIGS. 12A and 12B, if the distance L was 45 μm or less, the optical output of the surface electrode type was greater than that of the double-sided electrode type irrespective of the magnitude of the gap Lac. In the prior art, people took it for granted that a smaller amount of current should flow through the surface electrode type than through the double-sided electrode type and that the surface electrode type should have a lower optical output than the double-sided electrode type. However, the result shown in FIGS. 12A and 12B are contrary to such popular belief in the prior art. And such results would not be obtained unless the GaN substrate and the semiconductor layers have as low dopant concentrations as in a light-emitting diode that has been fabricated by m-plane growth process. In the double-sided electrode type, current flows vertically through the substrate and the semiconductor layers. However, if the dopant concentration is as low as in m-plane grown semiconductors, the advantage of the double-sided electrode type over the surface electrode type decreases. And by adopting the configuration of the present invention, the optical output can be further increased with the surface electrode type used.

This could also be confirmed based on results of calculations of the emission intensity distribution in the active layer. FIG. 13 is a graph showing the emission intensity distribution on the plane A-A′ shown in FIG. 8. In FIG. 13, the ordinate represents the rate of recombination of spontaneous emission Rsp and the abscissa represents the distance y from the counter edge of the cathode electrode layer to the point of emission. The results shown in FIG. 13 were obtained by setting the n-type dopant concentration to be 5×10¹⁷ cm⁻³, setting the anode-cathode electrode gap Lac to be 1 μm, and changing the anode electrode length La within the range of 10 μm through 400 μm.

The present inventors made calculations on a structure in which the cathode electrode layer 6 was arranged on right- and left-hand sides of the anode electrode layer 5 as shown in FIG. 10A. In the graph shown in FIG. 13, the results of calculations obtained from a light-emitting diode of the double-sided electrode type are also indicated by the dotted line as a comparative example, in which the n-type GaN substrate (with an n-type dopant concentration of 5×10¹⁷ cm⁻³) had a thickness of 100 μm.

As can be seen from the graph shown in FIG. 13, the rate of recombination Rsp of the double-sided electrode type is between the rate of recombination Rsp when La=80 μm and the rate of recombination Rsp when La=100 μm. And once the anode electrode length La exceeds 90 μm, the rate of recombination Rsp of the surface electrode type becomes lower than the rate of recombination Rsp of the double-sided electrode type. That is to say, if the interval (2·Lac+La) between two counter edges of the cathode electrode layer 6 that interpose the anode electrode layer 5 between them broadens, it becomes difficult to supply current to the active layer uniformly and the rate of recombination Rsp decreases. For example, the rate of emission when La=200 μm and the rate of emission when La=400 μm decreased to a half or less of the rate of emission when La=20 μm.

According to the graph shown in FIG. 13, the rate of recombination Rsp becomes the lowest when the distance y is approximately a half of the anode electrode length La. This means that the current density decreases most significantly in a portion of the active layer 3 that is located farthest away from the counter edge of the cathode electrode layer 6.

If the interval (2·Lac+La) between two counter edges of the cathode electrode layer 6 that interpose the anode electrode layer 5 between them narrows, then it means that the anode electrode length La shortens. In a layout in which the anode electrode length La is extremely short, the ratio of the total area of the anode electrode layer to the overall chip area becomes small. For that reason, the anode electrode length La is preferably set to be equal to or greater than 3 μm, and more preferably set to be equal to or greater than 10 μm. Supposing the lower limit of the gap Lac is 0.5 μm, the lower limit of the anode electrode length La is 3 μm, and L=(2·Lac+La)/2, then L has a lower limit of 2 μm.

Next, it will be described why the gap Lac between the anode electrode layer 5 and the cathode electrode layer 6 is set to be 4 μm or less.

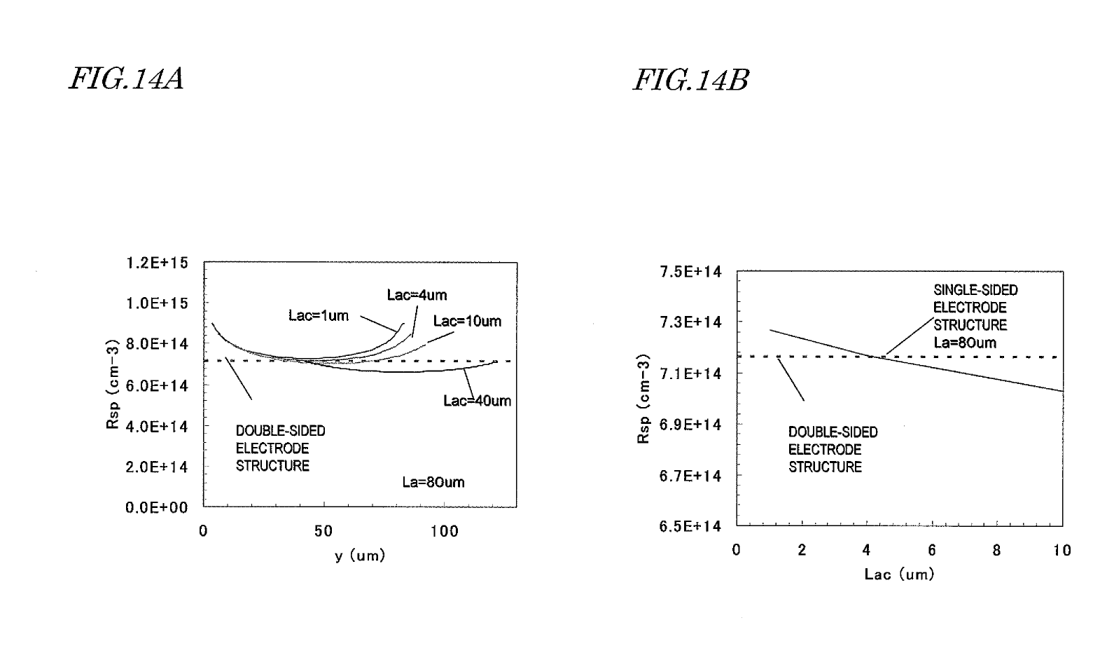

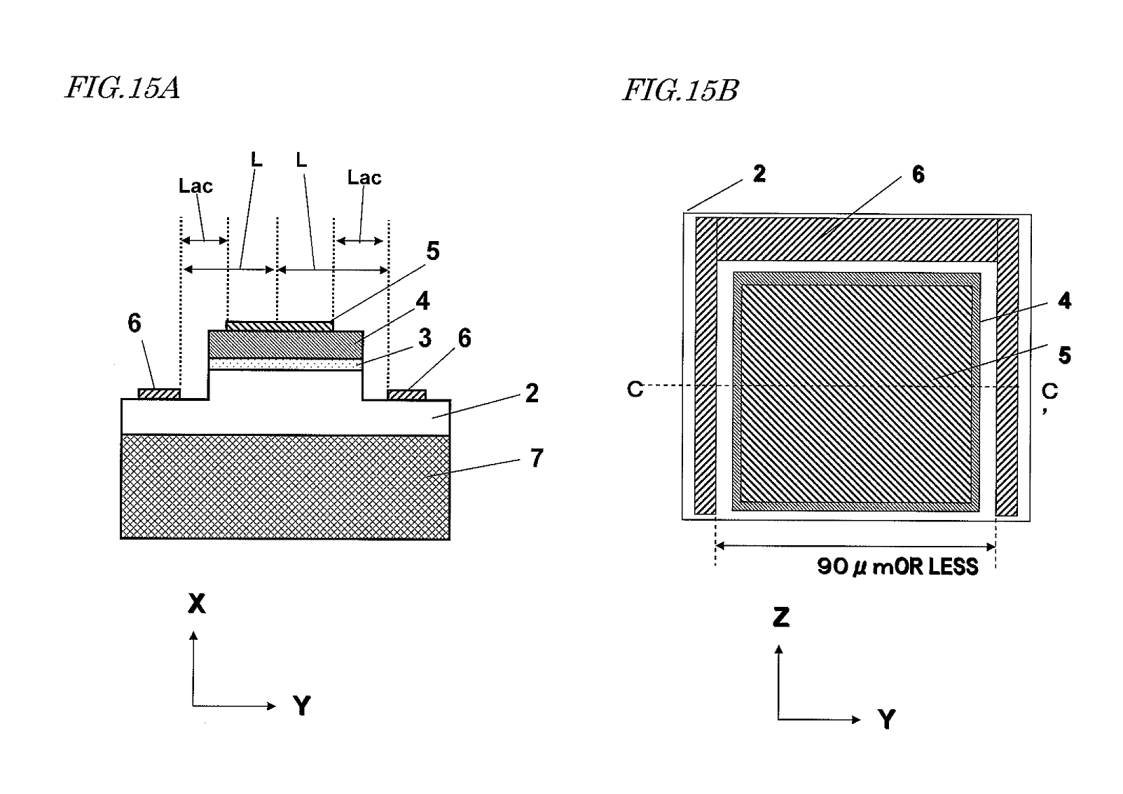

FIG. 14A is a graph showing how the distribution (on the cross section A-A′) of the rate of recombination Rsp of a light-emitting diode of the surface electrode type shown in FIG. 8 changed with Lac. In this case, the anode electrode length La was set to be 80 μm and the anode-cathode electrode gap Lac was changed within the range of 1 μm through 40 μm. FIG. 14B is a graph plotted based on the data shown in FIG. 14A and shows how the minimum value of the rate of recombination Rsp changes with the anode-cathode electrode gap Lac. In both of FIGS. 14A and 14B, the rate of recombination Rsp of the double-sided electrode type is indicated by the dotted line. As can be seen from FIG. 14B, the emission intensity of the surface electrode type can be higher than that of the double-sided electrode type by setting the anode-cathode electrode gap Lac to be 4 μm or less.

In a c-plane grown semiconductor, of which GaN crystals have good quality even if the n-type dopant concentration is 1×10¹⁸ cm⁻³ or more, the n-type semiconductors can have sufficiently high electrical resistance. That is why even a light-emitting diode of the double-sided electrode type, of which the c-plane GaN substrate has a thickness of 100 μm or more, can obtain a high optical output by applying a sufficiently high electric field to the active layer. Also, as for c-plane grown semiconductors, even if the light-emitting diode of the surface electrode type has an anode-cathode electrode gap Lac of 10 μm or more and an anode electrode length La of about 500 μm, the light-emitting diode can still have an optical output that is almost as high as that of the double-sided electrode type.

In a light-emitting diode that uses an m-plane GaN substrate, however, to achieve good crystallinity, the n-type dopant concentration should be set to be 1×10¹⁸ cm⁻³ or less (i.e., within the range of 1×10¹⁷ cm⁻³ through 1×10¹⁸ cm⁻³) with respect to both the substrate and epitaxially grown n-type conductor layers. That is why in the double-sided electrode type, due to high electrical resistance that the substrate with a thickness of about 100 μm has, a sufficiently high electric field cannot be applied to the active layer and a large optical output cannot be obtained. Also, if the arrangement of electrodes for a light-emitting diode of the surface electrode type that uses conventional c-plane grown semiconductors is applied as it is to a light-emitting diode that uses m-plane grown semiconductors, the emission obtained cannot be better than the double-sided electrode type. That is to say, if the conventional design for a surface electrode type, in which the anode-cathode electrode gap Lac is more than 4 μm, is adopted as it is, then the electrical resistance will increase so much between the electrodes and under the anode electrode layer that a sufficiently high electric field cannot be formed over the entire active layer and the optical output will decrease. On the other hand, if the anode electrode length becomes 100 μm or more, for example, a sufficiently high electric field cannot be formed in a portion of the active layer, which is located far away from the cathode electrode layer, the density of the current injected will decrease in some part of the active layer, and the distribution of the emission intensity will become uneven.

In contrast, according to the present invention, the gap between the cathode electrode layer and the anode electrode layer is narrowed and the anode electrode layer is arranged within a predetermined distance from an edge of the cathode electrode layer. As a result, the variation in potential between the electrodes and the potential difference between the n-type conductor layer of the active layer and the cathode electrode layer can be reduced. Consequently, a sufficiently high electric field can be applied to the active layer.

On top of that, as the anode electrode length La decreases, the distance to go for electrons in an n-type semiconductor layer to reach an n-electrode layer can be shortened. As a result, the heat generated in the n-type semiconductor layer can be reduced.

It should be noted that the anode electrode layer may be made of either a conductor material that reflects light or a transparent electrode material. If the anode electrode layer is made of a light reflecting material, the light-emitting diode is preferably flip-chip bonded so as to output light through the back surface of the substrate. On the other hand, if the anode electrode layer is made of a transparent material, then the light may be output through the surface of the light-emitting diode element with the electrodes.

### Embodiment 2

FIGS. 15A and 15B are respectively a cross-sectional view and a top view illustrating a second preferred embodiment of a light-emitting diode according to the present invention. FIG. 15A is a cross-sectional view as viewed on the plane C-C′ shown in FIG. 15B. In FIGS. 15A and 15B, any component having substantially the same function as its counterpart of the first preferred embodiment described above is identified by the same reference numeral. The light-emitting diode of this preferred embodiment has a different electrode layer layout from its counterpart of the first preferred embodiment described above.

In this preferred embodiment, an anode electrode layer 5 is arranged inside of a U- (or C-) cathode electrode layer 6. The electrode gap Lac is 4 μm or less and the anode electrode layer 5 is located at a distance of 45 μm or less from the counter edge of the cathode electrode layer 6.

According to this preferred embodiment, the edges of three out of the four sides of the rectangular anode electrode layer 5 are located close to, and face, their associated edges of the cathode electrode layer 6. That is why an electric field can be applied more easily from the cathode electrode layer 6 onto the entire active layer 3 that is located right under the anode electrode layer 5, and therefore, the emission intensity increases. For that reason, even if the chip area is reduced, the required active layer area can be ensured easily. On top of that, since the electrode layers have a simple planar layout, photolithographic and etching processes to expose the n-type semiconductor layers 2 can be simplified, too.

### Embodiment 3

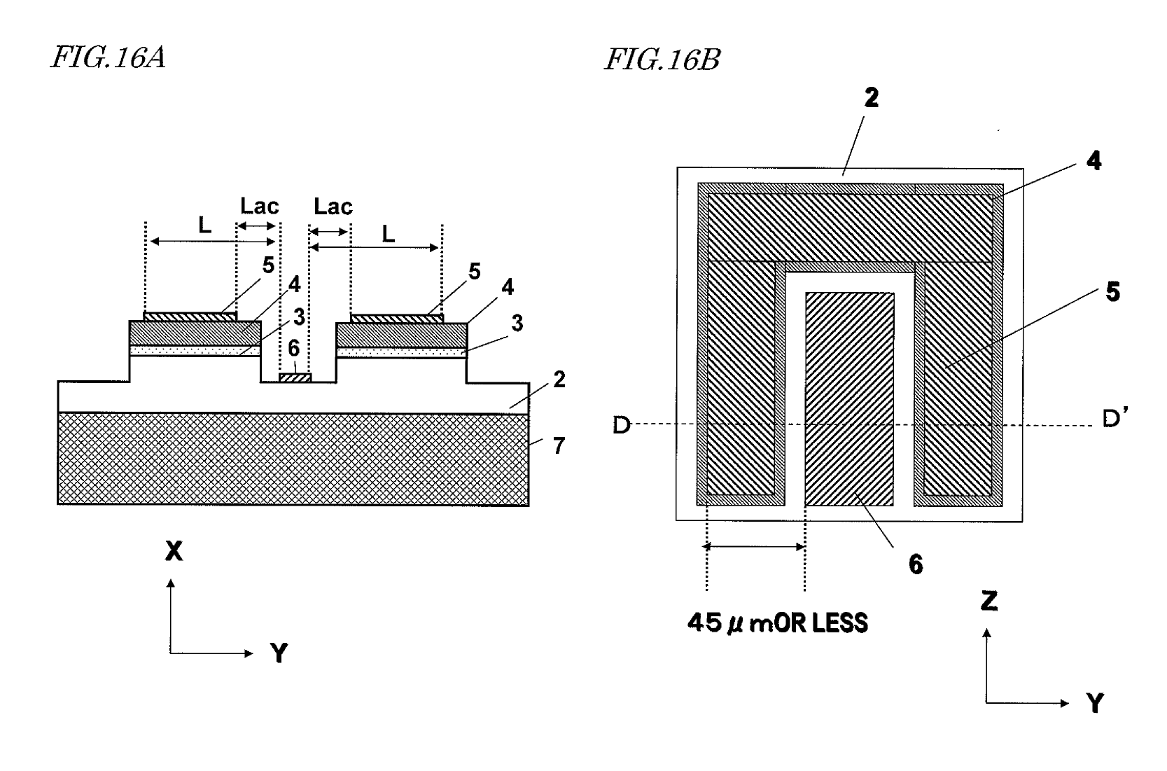

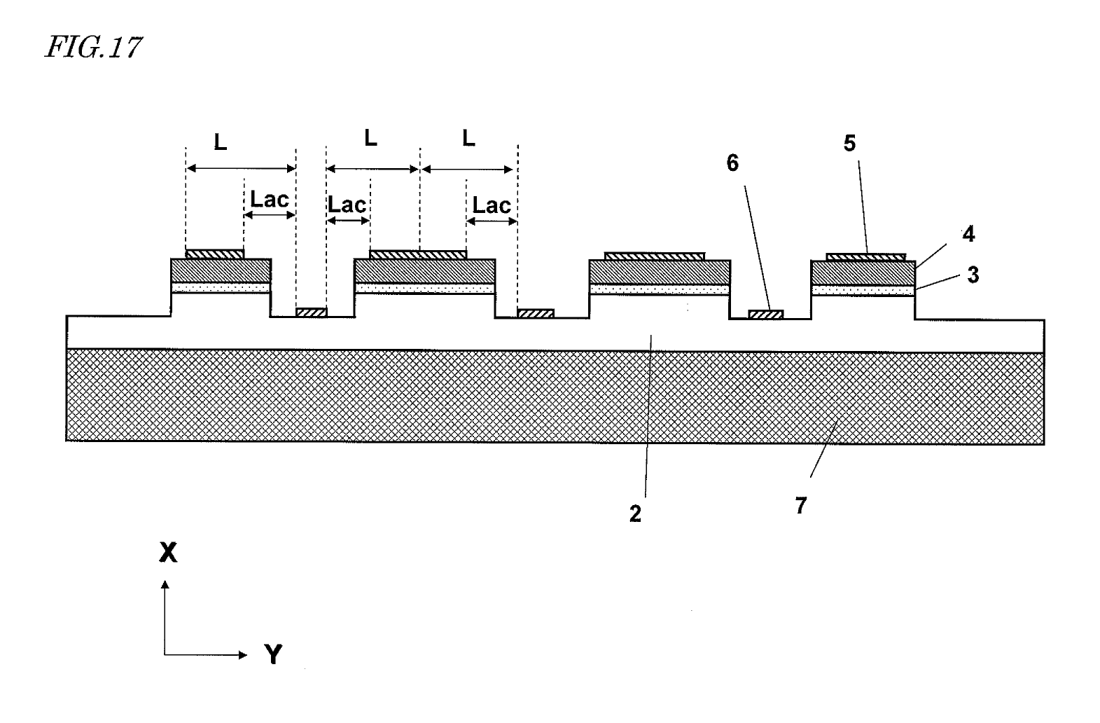

FIGS. 16A and 16B are respectively a cross-sectional view and a top view illustrating a third preferred embodiment of a light-emitting diode according to the present invention. FIG. 16A is a cross-sectional view as viewed on the plane D-D′ shown in FIG. 16B. In FIGS. 16A and 16B, any component having substantially the same function as its counterpart of the first preferred embodiment described above is identified by the same reference numeral. The light-emitting diode of this preferred embodiment has a different electrode layer layout from its counterpart of the first preferred embodiment described above.

In this preferred embodiment, a cathode electrode layer 6 is arranged inside of a U- (or C-) anode electrode layer 5. The electrode gap Lac is 4 μm or less and the anode electrode layer 5 is located at a distance of 45 μm or less from the counter edge of the cathode electrode layer 6.

According to this preferred embodiment, the edges of three out of the four sides of the rectangular cathode electrode layer 6 are located close to, and face, their associated edges of the anode electrode layer 5. Since the anode electrode layer 5 has a U- (or C-) planar shape, the active layer 3 has the same U- (or C-) planar shape. Thus, according to this preferred embodiment, even if the chip area is reduced, the required active layer area can be ensured easily. On top of that, since the electrode layers have a simple planar layout, photolithographic and etching processes to expose the n-type semiconductor layers 2 can be simplified, too.

### Embodiment 4

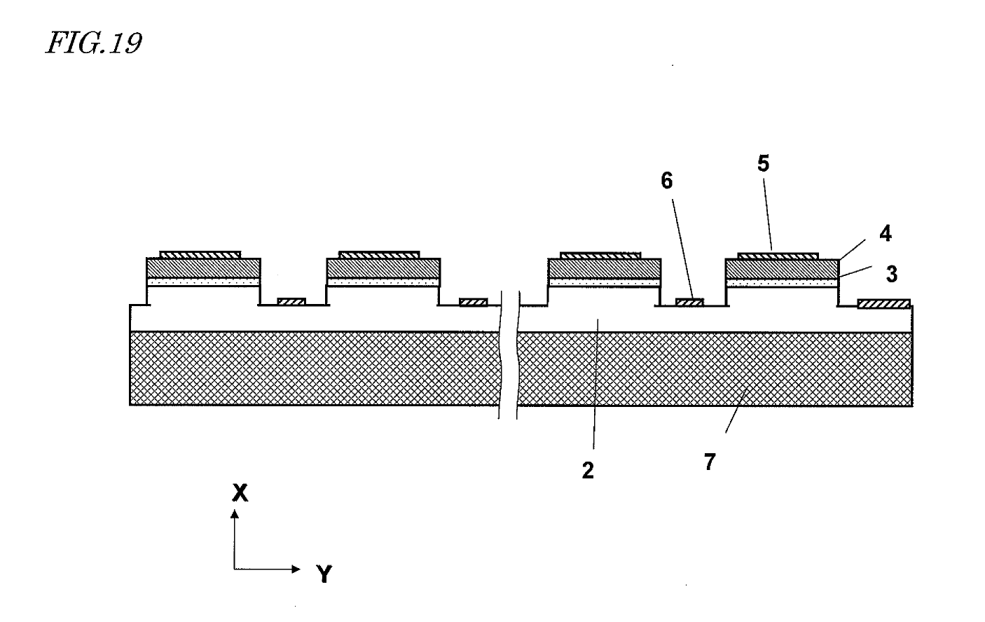

FIGS. 17 and 18 are respectively a cross-sectional view and a top view illustrating a fourth preferred embodiment of a light-emitting diode according to the present invention. FIG. 17 is a cross-sectional view as viewed on the plane E-E′ shown in FIG. 18. Although not shown, cross sections as viewed on the planes F-F′ and G-G′ shown in FIG. 18 are basically the same as the structure shown in FIG. 17. In FIGS. 17 and 18, any component having substantially the same function as its counterpart of the first preferred embodiment described above is identified by the same reference numeral. The light-emitting diode of this preferred embodiment has a different electrode layer layout from its counterpart of the first preferred embodiment described above.

According to this preferred embodiment, the anode electrode layer 5 is arranged so as to fill the gap between circular electrodes (cathode electrodes) that form the cathode electrode layer 6. Although there are a number of circular electrodes in the single light-emitting diode element, those circular electrodes are connected together with a conductor layer or conductor wire.

In this preferred embodiment, the electrode gap Lac is also 4 μm or less and the anode electrode layer 5 is located at a distance of 45 μm or less from the counter edge of the cathode electrode layer 6.

According to this preferred embodiment, a number of cathode electrodes that form the layer 6 are arranged two-dimensionally, and therefore, the lengths of their counter edges can be increased for the relatively small combined area of the cathode electrode layer 6. That is to say, even if the area of the cathode electrode layer 6 itself has been decreased, the range that is located at a distance of 45 μm or less from the counter edges of the cathode electrode layer can easily have a large overall area. With such an arrangement, an electric field can be applied more easily from the cathode electrode layer 6 onto the entire active layer 3 that is located right under the anode electrode layer 5, and therefore, a sufficiently high optical output can be obtained.

According to this preferred embodiment, regions surrounding the light-emitting diodes are covered with the anode electrode layer 5, not the cathode electrode layer 6, as shown in FIG. 17. It should be noted that the respective circular electrodes that form the cathode electrode layer 6 can be electrically connected together by depositing an insulating film on the anode electrode layer 5 and then forming conductive wires thereon (i.e., by forming a double layer interconnect structure).

### Embodiment 5

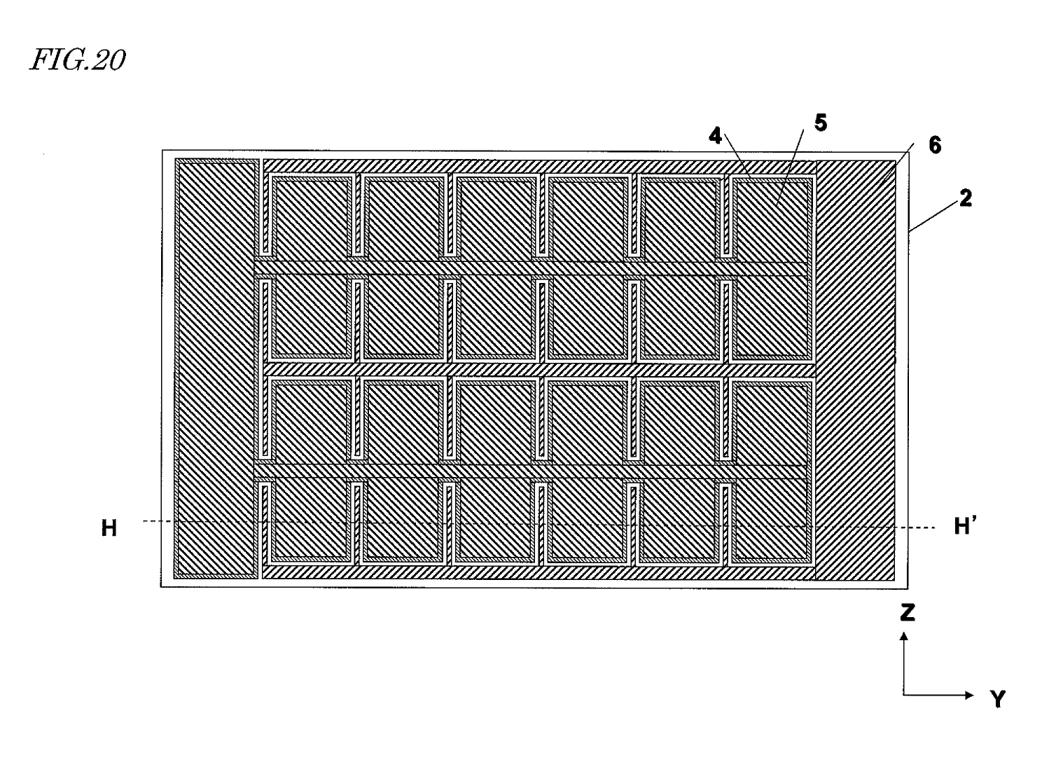

FIGS. 19 and 20 are respectively a cross-sectional view and a top view illustrating a fifth preferred embodiment of a light-emitting diode according to the present invention. FIG. 19 is a cross-sectional view as viewed on the plane H-H′ shown in FIG. 20. In FIGS. 19 and 20, any component having substantially the same function as its counterpart of the first preferred embodiment described above is identified by the same reference numeral. The light-emitting diode of this preferred embodiment has a different electrode layer layout from its counterpart of the first preferred embodiment described above.

The light-emitting diode element of this preferred embodiment has a cathode electrode layer 6 that has a lot of branched portions just like branches of a tree, and the anode electrode layer 5 is arranged between those branched portions. The electrode gap Lac is 4 μm or less and the anode electrode layer 5 is located at a distance of 45 μm or less from the counter edge of the cathode electrode layer 6.

In the arrangement of this preferred embodiment, the anode electrode layer 5 is surrounded with the cathode electrode layer 5. That is why a voltage can be applied more easily from the cathode electrode layer 6 onto the entire active layer that is located right under the anode electrode layer 5, and therefore, the emission intensity increases. According to this preferred embodiment, a light-emitting diode with good heat dissipation property, which can be used effectively in high-output applications, can be provided.

In the preferred embodiments of the present invention described above, the thickness of the substrate is set to be about 100 μm. However, even if the thickness of the substrate is reduced to as small as about 5 μm, the effects of the present invention can still be achieved. Specifically, compared to a light-emitting diode of a conventional surface electrode type with an electrode gap Lac of 10 μm or more, the optical output can be almost doubled, which is one of significant effects of the present invention. The effects achieved by the present invention are sufficiently advantageous over a light-emitting diode of the double-sided electrode type, of which the substrate thickness is greater than its anode-cathode electrode gap Lac.

Also, although the size of the anode electrodes is set to be relatively small according to the present invention, a connector portion (i.e., a pad) may be extended from the anode electrode illustrated in order to ensure a portion on which a bump is put on the anode electrode in a mounting process or where a wire binding process is carried out.

Furthermore, according to the present invention, the non-polar plane does not have to be an m plane but may also be an r plane or an a plane. In any case, the present invention is applicable effectively to any of various kinds of light-emitting diodes to be fabricated by growing semiconductors on a non-polar plane, in which it is usually more difficult to increase the dopant concentration than in a c-plane grown semiconductor layer.

Hereinafter, samples of a light-emitting diode that were actually made by the present inventors will be described.

First of all, the structures of three samples of light-emitting diodes will be described with reference to

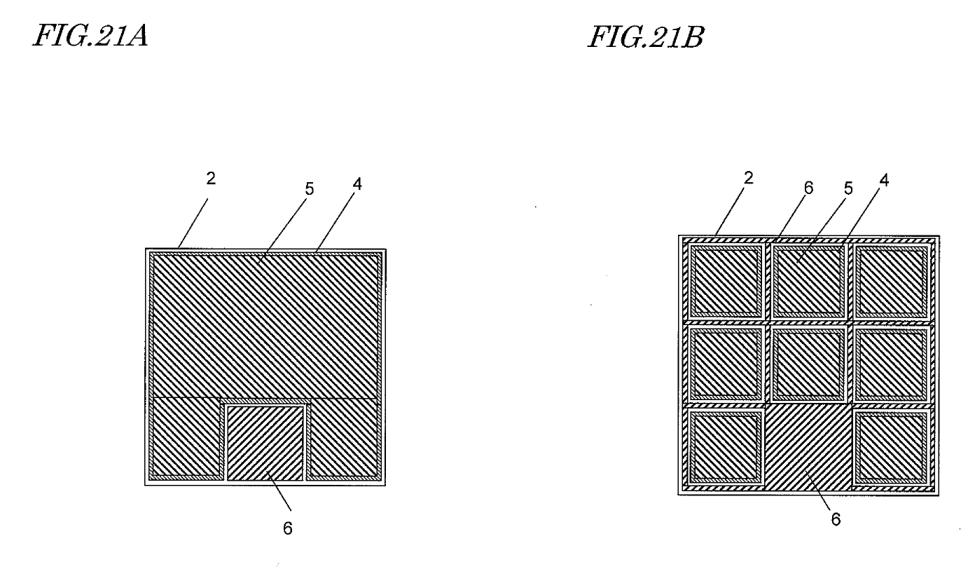

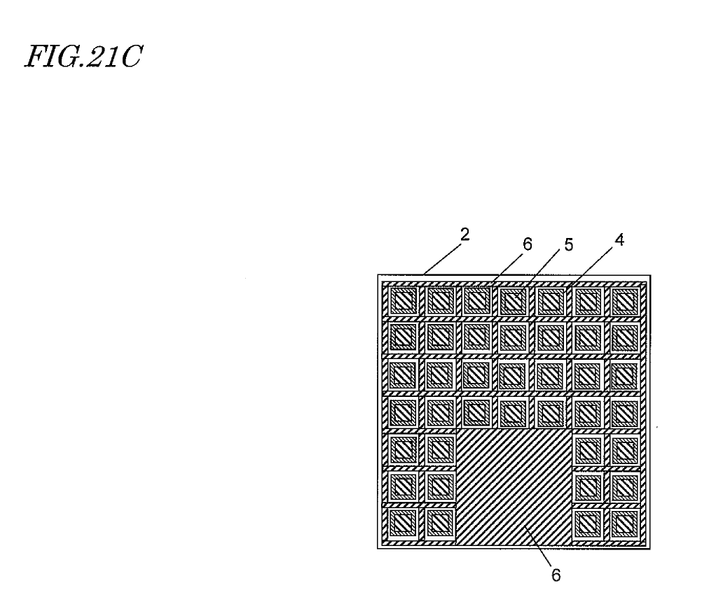

FIGS. 21A, 21B and 21C. Specifically, FIG. 21A is a top view of a sample light-emitting diode representing a comparative example, of which the distance L had a maximum value of 175 μm. FIG. 21B is a top view of another sample light-emitting diode representing a specific example of the present invention, of which the distance L had a maximum value of 45 μm. FIG. 21C is a top view of another sample light-emitting diode representing another specific example of the present invention, of which the distance L had a maximum value of 18 μm.

These samples have the same multilayer structure as the one shown in FIG. 8 except that their planar layouts of the anode electrode layer and the cathode electrode layer are different. Specifically, as shown in FIG. 8, each of these light-emitting diodes also includes: an n-type GaN substrate 7, of which the principal surface 7a is an m plane; an n-type semiconductor layer 2 that covers the principal surface of the n-type GaN substrate 7; an active layer 3 that is located on a first region 2a of the upper surface of the n-type semiconductor layer 2; a p-type semiconductor layer 4; an anode electrode layer 5; and a cathode electrode layer 6 arranged on a second region 2b of the upper surface of the n-type semiconductor layer 2. All of the n-type semiconductor layer 2, the active layer 3 and the p-type semiconductor layer have been grown epitaxially through an m-plane growth process.

In each of these samples, the principal surface of the n-type GaN substrate 7 had a size of 300 μm×300 μm, which is smaller than a square with a size of 500 μm each side. The n-type GaN substrate 7 had a dopant concentration of 5×10¹⁷ cm⁻³. The respective semiconductor layers had the following structures.

Specifically, the n-type semiconductor layer 2 was an n-GaN layer with a thickness of 3 μm and had a dopant concentration of 5×10¹⁷ cm⁻³. The active layer 3 was a quantum well layer, in which three pairs of InGaN well layers (with a thickness of 15 nm each) and GaN barrier layers (with a thickness of 15 nm each) were stacked one upon the other. The p-type semiconductor layer 4 was a p-GaN layer with a thickness of 0.3 μm and had a dopant concentration of 8×10¹⁸ cm⁻³.

In the comparative example illustrated in FIG. 21A, an anode electrode layer 5 is arranged so as to surround a cathode electrode layer 6 with a square upper surface (with a length of 90 μm each side) in three of its four sides. The distance L had a maximum value of 175 μm.

On the other hand, in the specific example of the present invention illustrated in FIG. 21B, eight anode electrodes, each having a square upper surface (with a length of 82 μm each side), are arranged to form an anode electrode layer 5 with a gap left between them. When viewed perpendicularly to the principal surface, the cathode electrode layer 6 has a generally grating shape. And the cathode electrode layer 6 has been patterned so as to surround each of the divided anode electrodes that form the layer 5 in all of the four sides thereof. In this specific example, the gap Lac is set to be 4 μm and the distance L is set to be 45 μm.

Likewise, in the specific example of the present invention illustrated in FIG. 21C, forty anode electrodes, each having a square upper surface (with a length of 28 μm each side), are arranged to form an anode electrode layer 5 with a gap left between them. When viewed perpendicularly to the principal surface, the cathode electrode layer 6 also has a generally grating shape. And the cathode electrode layer 6 has been patterned so as to surround each of the divided anode electrodes that form the layer 5 in all of the four sides thereof. In this specific example, the gap Lac is set to be 4 μm and the distance L is set to be 18 μm.

In the specific examples illustrated in FIGS. 21B and 21C, multiple (eight or more) divided anode electrodes are arranged to form a layer 5 on a single chip. Those divided electrodes are covered with a conductor film (not shown and will be referred to herein as an “anode electrode pad”) and electrically connected together.

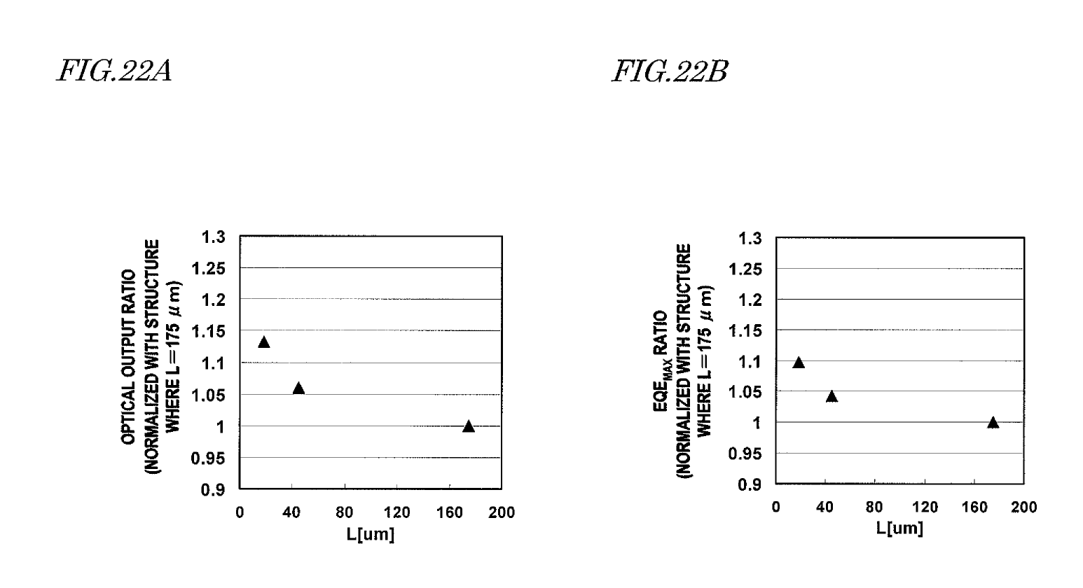

FIG. 22A is a graph showing the results of measurement of the optical outputs of the LED elements shown in FIGS. 21A, 21B and 21C. This graph shows the distance L dependence of the optical output when the amount of current flowing through the LED elements is supposed to be 10 mA. The ordinate represents a normalized value, which is defined with an optical output associated with L=175 μm supposed to be one.

FIG. 22B is a graph showing the results of measurement of the external quantum efficiencies (EQE) of the LED elements shown in FIGS. 21A, 21B and 21C. This graph shows the distance L dependence of the maximum value of the external quantum efficiency. The ordinate represents a normalized value, which is defined with an external quantum efficiency associated with L=175 μm supposed to be one.

It can be seen that if the distance L value is decreased from 45 μm to 18 μm, the optical output and the external quantum efficiency both increase. That is why the anode electrode layer 5 preferably has as many divided electrodes as possible and the size of each of those divided electrodes is preferably as small as possible. In the specific examples of the present invention, the anode electrode layer 5 is divided into eight or more electrodes. However, it is more preferred that the anode electrode layer be divided into ten or more (e.g., thirty or more) electrodes.

Normally, if the areas of the anode electrode layer and the active layer are reduced, the current density will increase and the optical output and external quantum efficiency of the LED will decrease. For that reason, such a structure in which the areas of the anode electrodes and active layer are reduced is not adopted by a c-plane GaN LED.

In an m-plane GaN LED, on the other hand, the quantum confinement Stark effect of carriers due to the presence of piezoelectric charges is not produced, and therefore, the thickness of the well layers can be increased compared to the c-plane GaN LED. That is why even if the m-plane GaN LED is operated with a high current density, neither the optical output nor the external quantum efficiency decreases and the effects of the present invention can be achieved significantly by reducing the distance L. In the c-plane GaN LED, the well layer usually has a thickness of about 3 nm. On the other hand, in the m-plane GaN LED, the well layer can have a thickness of 6 nm to 20 nm.

### INDUSTRIAL APPLICABILITY

A gallium nitride based compound semiconductor light-emitting diode element according to the present invention includes a semiconductor substrate of a gallium nitride based compound, of which the principal surface is a non-polar plane, and has an n-type dopant concentration of 1×10¹⁸ cm⁻³ or less, thus realizing good crystallinity. In addition, by adopting a special arrangement of electrodes, a sufficiently high voltage can be applied to the entire active layer, and therefore, a high optical output can be obtained. Consequently, the light-emitting diode element of the present invention can be used effectively as a light source for display devices, illumination units, and an LCD backlight.

### REFERENCE SIGNS LIST

1 n-type substrate
2 n-type conductive layer
3 active layer
4 p-type conductive layer
5 anode electrode layer
6 cathode electrode layer
7 m-plane n-type GaN substrate

1. A gallium nitride based compound semiconductor light-emitting diode element comprising:
a semiconductor substrate of a first conductivity type, which is made of a gallium nitride based compound, which has a principal surface and a back surface, and of which the principal surface is a non-polar plane;
a semiconductor layer of the first conductivity type, which is made of a gallium nitride based compound and which has been formed on the principal surface of the semiconductor substrate of the first conductivity type;
a semiconductor multilayer structure, which is arranged on a first region of the semiconductor layer of the first conductivity type and which includes a semiconductor layer of a second conductivity type that is made of a gallium nitride based compound and an active layer that is arranged between the semiconductor layer of the first conductivity type and the semiconductor layer of the second conductivity type;
a first electrode layer, which is arranged on a second region of the semiconductor layer of the first conductivity type; and
a second electrode layer, which is arranged on the semiconductor layer of the second conductivity type,
wherein a dopant of the first conductivity type added to the semiconductor substrate of the first conductivity type and the semiconductor layer of the first conductivity type has a concentration of 1×10¹⁸ cm⁻³ or less, and
wherein when viewed perpendicularly to the principal surface, a gap of 4 μm or less is left between the first and second electrode layers and the second electrode layer is arranged at a distance of 45 μm or less from an edge of the first electrode layer that faces the second electrode layer.

2.-15. (canceled)

16. The gallium nitride based compound semiconductor light-emitting diode element of claim 1, wherein the first electrode layer has a plurality of openings, and
wherein the second electrode layer includes electrodes, which are arranged inside of the openings of the first electrode layer, and
wherein the semiconductor multilayer structure has been divided into as many parts as the openings of the first electrode layer, and
wherein the first electrode layer has a conductive portion with a grating shape that defines the openings.

17. The gallium nitride based compound semiconductor light-emitting diode element of claim 16, wherein the active layer has a quantum well structure in which a well layer and a barrier layer are stacked one upon the other and the well layer has a thickness of 6 nm to 20 nm.

18. The gallium nitride based compound semiconductor light-emitting diode element of claim 17, wherein the number of the openings is eight or more.

19. The gallium nitride based compound semiconductor light-emitting diode element of claim 18, wherein the principal surface of the semiconductor substrate of the first conductivity type is smaller than a square with a length of 50 μm each side.

20. The gallium nitride based compound semiconductor light-emitting diode element of claim 1, wherein current that flows between the first and second electrode layers when the diode element operates has a density of 150 A/cm² or more.

21. The gallium nitride based compound semiconductor light-emitting diode element of claim 1, wherein the first electrode layer has multiple extended portions that run in a first direction, and
wherein the second electrode layer has a portion that is located in a region interposed between two of the extended portions of the first electrode layer.

22. The gallium nitride based compound semiconductor light-emitting diode element of claim 21, wherein the first electrode layer has at least one interconnecting portion that electrically connects the multiple extended portions together, and
wherein the interconnecting portion runs in a second direction, which is different from the first direction.

23. The gallium nitride based compound semiconductor light-emitting diode element of claim 1, wherein the second electrode layer has multiple extended portions that run in a first direction, and
wherein the first electrode layer has a portion that is located in a region interposed between two of the extended portions of the second electrode layer.

24. The gallium nitride based compound semiconductor light-emitting diode element of claim 1, wherein each of the first and second electrode layers has multiple extended portions that run in a first direction, and
wherein the extended portions of the first electrode layer and the extended portions of the second electrode layer are arranged alternately in a second direction that is different from the first direction.

25. The gallium nitride based compound semiconductor light-emitting diode element of claim 24, wherein the first electrode layer has at least one first interconnecting portion that electrically connects its own extended portions together, and
wherein the second electrode layer has at least one second interconnecting portion that electrically connects its own extended portions together, and
wherein the first and second interconnecting portions run in a second direction that is different from the first direction.

26. The gallium nitride based compound semiconductor light-emitting diode element of claim 1, wherein the second electrode layer has a plurality of openings, and
wherein the first electrode layer includes electrodes, which are arranged inside of the openings of the second electrode layer.

27. The gallium nitride based compound semiconductor light-emitting diode element of claim 26, wherein when viewed perpendicularly to the principal surface, those electrodes that are arranged inside of the openings of the second electrode layer have a curved outer edge.
